(19) United States
(12) Patent Application Publication
(10) Pub. No.: US 2016/0222143 A1
(43) Pub. Date: Aug. 4, 2016

(54) Nanoporous polymeric material, nanoporous polymeric material membrane for selective absorption and manufacturing processes

(71) Applicants: CONSEJO NACIONAL DE INVESTIGACIONES CIENTIFICAS Y TECNICAS (CONICET), Ciudad Autonoma de Buenos Aires (AR); UNIVERSIDAD DE BUENOS AIRES, Ciudad Autonoma de Buenos Aires (AR); COMISION NACIONAL DE ENERGIA ATOMICA (CNEA), Ciudad Autonoma de Buenos Aires (AR); YPF TECNOLOGIA S.A., Ciudad Autonoma de Buenos Aires (AR)

(72) Inventors: Silvia Nair GOYANES, Provencia de Buenos Aires (AR); Norma D'ACCORSO, Ciudad Autonoma de Buenos Aires (AR); Diana GRONDONA, Provencia de Buenos Aires (AR); Andres Arias DURAN, Ciudad Autonoma de Buenos Aires (AR); Gerardo RUBIOLO, Provencia de Buenos Aires (AR); Gustavo Luis BIANCHI, Ciudad Autonoma de Buenos Aires (AR)

(21) Appl. No.: 14/757,480

(22) Filed: Dec. 23, 2015

Related U.S. Application Data
(60) Provisional application No. 62/096,441, filed on Dec. 23, 2014.
(60) Provisional application No. 62/237,877, filed on Oct. 6, 2015.

(51) Int. Cl. C08F 138/02; B01J 20/28; B01J 20/32; C09K 3/32; H01J 37/32; C02F 1/44; C02F 1/40; B01D 15/26; B01D 71/44; B01D 69/02; B01D 67/00; B01J 20/26; C02F 1/28

(52) U.S. Cl. CPC C08F 138/02; B01J 20/262; B01J 20/28033; B01J 20/3214; C09K 3/32; H01J 37/32082; C02F 1/285; C02F 1/40; B01D 15/26; B01D 71/44; B01D 69/02; B01D 67/0037; C02F 1/44; H01J 2237/332; C02F 2101/32

(57) ABSTRACT

A nanoporous material made of aggregated polymeric nanoparticles wherein at least 40% of the nanoparticles have a diameter above 50 nm, and a process for producing thereof. Also, a nanoporous material membrane, a process for its manufacturing, and to a method using said membrane for separating hydrophobic compounds from its mixtures in water

### FIELD OF THE INVENTION

The instant invention relates to the field of nanomaterials. More specifically, the instant invention relates to a new nanoporous material and to a process for manufacturing it. Even more specifically, the instant invention relates to a nanoporous material membrane, to a process for its manufacturing, and to a method using said membrane for separating hydrophobic compounds from its mixtures in water.

### BACKGROUND OF THE INVENTION

Nanostructured materials are materials made by the assembly of building blocks whose size is typically within the range of 1-100 nm. The interest of these materials lays in that by controlling and manipulating the architecture of the material at a nanometric scale it is possible to obtain materials with properties tailored for specific needs, in particular those properties related with phenomena occurring at a nanoscale, such as for example catalysis, diffusion, adsorption, etc.

A particular class of nanostructured materials are nanoporous materials, which have been obtained from polymers, carbon, glass, aluminosilicates, oxides or metals. These materials are characterized by having a large specific surface area, a large pore volume and typically a relatively uniform pore size. Presence of pores at a nanometric scale confers a wide spectrum of properties to the nanoporous materials, which would have been absent if nanopores were not present. In the field of functional material chemistry, nanoporous materials are defined as those materials which have pores with diameter between 1 and 100 nm. This definition co-exists and overlaps with the IUPAC classification, which classifies pores in micropores (diameter less than 2 nm), mesopores (between 2 and 50 nm) and macropores (more than 50 nm).

The big attractive of nanoporous materials is that variations in their structure happen at the scale in which atoms and molecules interact, and for this reason manipulating materials at this small scale allows for a precise control of such interactions as well as tailoring materials with desired properties and functionalities. Thanks to its versatility and wide range of possibilities, nanoporous materials have found since long ago many functional applications in catalysis, filtration, adsorption and separation, for mentioning a few examples.

The particular properties of nanoporous materials are determined by both their chemical composition and their architecture at a nanometric scale, which may comprise from a highly ordered structure to a disordered structure. A class of nanoporous material of disordered structure are materials formed by aggregation of nanometric particles, which form interconnected aggregations or agglomerations, leaving free spaces between them and thus defining the pores. In these materials, then, nanostructure—and as a result the porosity parameters, such as specific surface area, total pore volume, pore size distribution, contribution to pore volume by pore size, contribution to pore area by pore size, etc.—is defined mainly by the size of the individual particles.

An example of nanoporous materials formed by aggregation of nanometric particles are those materials obtained by different methods of plasma polymerization from carbon sources such as acetylene. These materials have demonstrated to have hydrophobic properties and to be able to absorb oils and hydrocarbon derivatives, and have been proposed as useful in liquid separation, as for example water filtration and cleaning of spills of oil and its derivatives.

In a prior publication (Arias-Duran et al., Thin films of polymerized acetylene by RF discharge and its benzene absorption ability, Surface & Coatings Technology 216 (2013.) 285-190), the instant inventors disclosed the production, by acetylene plasma polymerization, of a material in the form of a continuous film, which is able of absorbing benzene. The water contact angle for that material is about 66°, that is, although it does not absorb water, the material is lightly hydrophilic according to the classification proposed in Surface design: applications in bioscience and nanotechnology (Förch, Holger y Jenkins (2009); Wiley-VCH. p. 471).

Dai et al. (Wei Dai et al., Porous Carbon Nanoparticle Networks with Tunable Absorbability, Scientific Reports 3, Art. No. 2524, 28 de Agosto 2013) and patent application US 2014/0116936 A1 disclose a method for manufacturing a nanoporous material based in an acetylene polymer, as well as the nanoporous material produced by said method. Said material is able to repel water and to absorb hydrophobic compounds, and has a specific surface area of 148 m²/g

Depending on the specific uses for which nanoporous materials are required, the desirable characteristics of these may vary. For example, while in most applications a larger specific surface area is desirable, for some uses nanoporous materials would be preferable or necessary in which for example most of the pores are small (for instance for acting as support for catalyzers or for retaining or absorbing molecules a few nanometers in size, such as octanes and heptanes among other molecules), or which are highly hydrophobic, or present good adherence to the substrate, or which combine porosity at a nanometric scale with a given chemical composition or molecular architecture with specific properties. In general, materials which could be produced by simple, safe and economically feasible processes are desirable.

According to the foregoing, there is currently a need for new nanoporous materials, with enhanced and/or new functionalities, which allow its employment in new uses or which could replace advantageously the existing nanoporous materials in the uses in which these are usually employed.

### BRIEF DESCRIPTION OF THE INVENTION

The inventors have created a new nanoporous material from acetylene or other carbon source which solves the problems from the prior art and which has additional advantages which will result evident from the following description.

Therefore, according to one of its aspects, the instant invention comprises a nanoporous material made of aggregated polymeric nanoparticles, wherein the polymer has a spatial conformation of open network comprising the repetitive hydrocarbon structure of formula I:

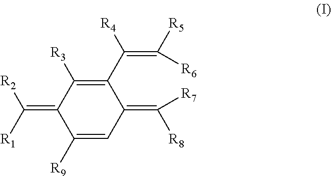

wherein R1-R9 are molecular groups which bind with other structures of formula I, each independently selected from H, (C₁₋₅) alkylene- or (C₆₋₁₀) cycloalkylene-(C₁₋₅) alkylene-;

wherein the alkylene groups can be saturated or have one or more carbon-carbon double bonds, wherein the groups cycloalkylene have one or more carbon-carbon double bonds, and wherein one or more carbon atoms of the alkylene and cycloalkylene chains can be substituted by a —O— bridge or by —OH,

and wherein at least 40% of the nanoparticles has a diameter above 50 nm.

The alkylene binding molecular group can be for example —CH₂—CH═CH— or —CH═CH—, and the cycloalkylene binding molecular group can be for example —C₆H₈— and has at least one insaturation.

According to a particular embodiment, alone or in combination with the foregoing or following embodiments, at least 60% of the nanoparticles has a diameter above 50 nm.

According to another particular embodiment, alone or in combination with the foregoing or following embodiments, the nanoporous material of the invention has nanoparticles with a diameter between 8 and 200 nm.

According to another embodiment, alone or in combination with the foregoing or following embodiments, the nanoporous material of the invention has a specific surface area, measured according to the BET (Brunauer-Emmett-Teller) method, between 141 and 173 m²/g, and preferably at least 157 m²/g.

According to another embodiment, alone or in combination with the foregoing or following embodiments, in the nanoporous material of the invention the pores of radius equal or less than 2 nm contribute with at least 60% of the porosity measured according to the BJH (Barrett, Joyner & Halenda) method. In a more particular embodiment, in the nanoporous material of the invention the contribution to porosity of each pore size has the following distribution:

| Mean | |
|---|---|
| radius of | |
| the pore | Contribution to total |
| (nm) | pore area (%) |
| 114.54 | 0.61 ± 0.06 |
| 61.92 | 1.13 ± 0.11 |
| 42.07 | 0.96 ± 0.10 |
| 23.67 | 2.74 ± 0.27 |
| 15.40 | 2.25 ± 0.23 |
| 11.32 | 2.09 ± 0.21 |
| 8.91 | 1.96 ± 0.20 |
| 7.35 | 1.93 ± 0.19 |
| 6.13 | 2.29 ± 0.23 |
| 5.35 | 1.59 ± 0.16 |
| 4.45 | 3.38 ± 0.34 |
| 3.62 | 3.46 ± 0.35 |
| 3.04 | 4.47 ± 0.45 |
| 2.60 | 3.88 ± 0.39 |
| 2.26 | 4.31 ± 0.43 |
| 1.99 | 4.62 ± 0.46 |
| 1.76 | 4.88 ± 0.49 |
| 1.56 | 5.28 ± 0.53 |
| 1.40 | 5.92 ± 0.59 |
| 1.25 | 7.52 ± 0.75 |
| 1.11 | 9.51 ± 0.95 |
| 0.98 | 10.52 ± 1.05 |
| 0.91 | 7.10 ± 0.71 |
| 0.86 | 7.59 ± 0.76 |

According to another embodiment, alone or in combination with the foregoing or following embodiments, the polymer comprises at least 68% of carbon and at least 5% of hydrogen. Additionally, in a more particular embodiment, the polymer may have oxygen in a percentage below 20%.

According to another aspect, the instant invention provides a process for producing the nanoporous material of the invention, which comprises carrying out a plasma polymerization comprising the steps of:
a) feeding a plasma reactor with a carbon source selected from the group consisting of acetylene, methane, ethane, benzene, and combinations thereof,
b) performing and maintaining the discharge of radiofrequency at a pressure equal to or higher than 1 mbar using a discharge of radiofrequency with a potence in the range of 10-550 W.

In a preferred embodiment of the process for producing the nanoporous material of the invention, the carbon source is acetylene.

According to another embodiment, alone or in combination with the foregoing or following embodiments, the process for producing the nanoporous material of the invention is performed with a continuous voltage bias between −3 V and −450 V.

According to another aspect the present invention relates to a nanoporous material produced by the process of the invention. According to this aspect, the nanoporous material is in the form of a sheet or as a powder

According to another aspect the present invention relates to a substrate coated with the nanoporous material of the invention. The substrate can be for example glass, metal, ceramic, or a polymer, and the nanoporous material forms a film on at least one of its surfaces. In a particular embodiment, the coated substrate is a metallic, ceramic, or polymeric mesh.

According to yet another aspect, the instant invention relates to a process for coating at least a surface of a substrate with the nanoporous material of the invention. Said process comprises the steps of:
a) providing the substrate whose coating is desired inside a plasma reactor,
b) feeding the plasma reactor with a carbon source selected from the group consisting of acetylene, methane, ethane, benzene, and combinations thereof, and
c) performing and maintaining the discharge of radiofrequency at a pressure equal to or higher than 1 mbar using a discharge of radiofrequency with a power in the range of 10-550 W.

In a particular embodiment, the process for coating at least a surface of a substrate with the nanoporous material of the invention is carried out with a continuous voltage bias between −3 V y −450 V.

In a particular embodiment, the process for coating at least a surface of a substrate with the nanoporous material of the invention, alone or in combination with the foregoing or following embodiments, the substrate is glass, metal, ceramic, or a polymer, such as a glass, metal, ceramic, or polymeric sheet, and the nanoporous material forms a film on at least one of its surfaces. More particularly, the substrate can be a metallic, ceramic, or polymeric mesh.

According to even another aspect, the invention relates to a process for modifying the wettability of the nanoporous material of the invention for making it hydrophilic, said process comprising exposing said nanoporous material to ultraviolet radiation, such as exposing the nanoporous material to ultraviolet radiation for at least 5 minutes at a power of at least 4000 μW/cm². In a particular embodiment, the nanoporous material is in the form of a sheet, and the ultraviolet radiation is applied only to one of its sides. According to a more particular embodiment, the sheet of nanoporous material is deposited on a metallic, ceramic or polymeric mesh. In another particular embodiment, the nanoporous material is in the form of a powder.

According to an additional aspect, the invention relates to a sheet of nanoporous material of the invention, wherein one side is highly hydrophobic and the other side is hydrophilic.

According to another additional aspect, the invention relates to a filter for separating or retaining organic compounds in which the filtering material comprises or consists of the nanoporous material of the invention.

According to yet another additional aspect, the invention relates to a membrane for immobilizing enzymes which comprises or consists on the nanoporous material of the invention.

According to yet another aspect, the invention relates to a composition which protects from ultraviolet radiation which comprises the nanoporous material of the invention. Said composition can be for example a cosmetic composition or a coating or protective material of use in masonry, construction, or carpentry, such as a paint, lacquer, varnish, asphalt coating or wood protective product. According to an embodiment, in the protective composition of the instant invention the nanoporous material of the invention is in the form of nanoparticles.

According to yet another aspect, the invention relates to a method for removing hydrophobic compounds from water, which comprises absorbing the hydrophobic compounds in the nanoporous material of the invention. According to an embodiment, in the method of the invention, the hydrophobic compound/s are organic compounds immiscible in water. According to another embodiment, alone or in combination with the foregoing or following embodiments, the hydrophobic compounds are oils or fats. In another embodiment, alone or in combination with the foregoing or following embodiments, the hydrophobic compounds are paraffins, oleffins, aromatic compounds such as benzene, and petroleum or its derivatives. According to another embodiment, alone or in combination with the foregoing or following embodiments, the nanoporous material absorbing the hydrophobic compounds is free (that is to say, is not deposited on a substrate). According to another embodiment, alone or in combination with the foregoing or following embodiments, the nanoporous material absorbing the hydrophobic compounds is deposited on a substrate, such as a metallic mesh, a polymeric fibers mesh, or a natural fibers mesh, for example fabric made of synthetic polymeric fibers or natural fibers, acting as an absorbent cloth.

According to another of its preferred aspects, the invention relates to a selective absorption membrane comprising a substrate coated by a nanoporous material according to the present invention, wherein the substrate is selected from a metallic mesh, a synthetic fibers mesh, or a natural fiber mesh.

Accordingly, in one of its aspects, the present invention relates to a selective absorption membrane for hydrocarbons, mineral, animal or vegetable oils comprising a nanoporous material formed by aggregated polymeric nanoparticles, wherein the polymer has a spatial conformation of open network comprising the repetitive hydrocarbon structure of formula I:

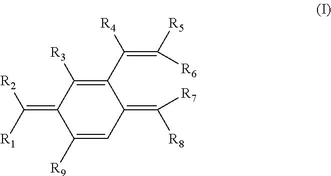

wherein R1-R9 are molecular groups which bind with other structures of formula I, each independently selected from H, (C₁₋₅) alkylene- or (C₆₋₁₀) cycloalkylene-(C₁₋₅) alkylene-; wherein the alkylene groups can be saturated or have one or more carbon-carbon double bonds, wherein the groups cycloalkylene have one or more carbon-carbon double bonds, and wherein one or more carbon atoms of the alkylene and cycloalkylene chains can be substituted by a —O— bridge or by —OH,

wherein at least 40% of the nanoparticles has a diameter above 50 nm, and wherein said nanoporous material coats at least one side of the substrate selected from a metallic mesh, a synthetic fibers mesh, or a natural fibers mesh, such as a fabric of synthetic polymeric fibers or a fabric of natural fibers.

The alkylene binding molecular group can be for example —CH₂—CH═CH— or —CH═CH—, and the cycloalkylene binding molecular group can be for example —C₆H₈— with at least one insaturation.

According to a preferred embodiment, the nanoporous material coats only one side of the substrate.

According to a preferred embodiment, the substrate is a metallic mesh, preferably a steel mesh, preferably between 50 and 400 mesh, preferably between 80 and 200 mesh.

According to a preferred embodiment, the substrate is a synthetic fibers mesh. Examples of synthetic fibers are oleffinic, polyvinylic, acrylic fibers, etc.

According to another preferred embodiment, the substrate is a natural fibers mesh such as cellulosic fibers.

According to a particular embodiment, alone or in combination with the foregoing or following embodiments, at least 60% of the polymer nanoparticles has a diameter above 50 nm.

According to another particular embodiment, alone or in combination with the foregoing or following embodiments, the nanoporous material of the invention has nanoparticles with a diameter between 8 and 200 nm.

According to another embodiment, alone or in combination with the foregoing or following embodiments, the nanoporous material in the membrane of the invention has a specific surface area, measured according to the BET (Brunauer-Emmett-Teller) method, between 141 and 173 m²/g, and preferably at least 157 m²/g.

According to another embodiment, alone or in combination with the foregoing or following embodiments, in the nanoporous material of the membrane of the invention the pores of radius equal or less than 2 nm contribute with at least 60% of the porosity measured according to the BJH (Barrett, Joyner & Halenda) method. In a more particular embodiment, in the nanoporous material of the membrane of the invention the contribution to porosity of each pore size has the following distribution:

| Mean radius of the pore | Contribution to total |
|---|---|
| (nm) | pore area (%) |
| 114.54 | 0.61 ± 0.06 |
| 61.92 | 1.13 ± 0.11 |
| 42.07 | 0.96 ± 0.10 |
| 23.67 | 2.74 ± 0.27 |
| 15.40 | 2.25 ± 0.23 |
| 11.32 | 2.09 ± 0.21 |
| 8.91 | 1.96 ± 0.20 |
| 7.35 | 1.93 ± 0.19 |
| 6.13 | 2.29 ± 0.23 |
| 5.35 | 1.59 ± 0.16 |
| 4.45 | 3.38 ± 0.34 |
| 3.62 | 3.46 ± 0.35 |
| 3.04 | 4.47 ± 0.45 |
| 2.60 | 3.88 ± 0.39 |
| 2.26 | 4.31 ± 0.43 |
| 1.99 | 4.62 ± 0.46 |
| 1.76 | 4.88 ± 0.49 |
| 1.56 | 5.28 ± 0.53 |
| 1.40 | 5.92 ± 0.59 |
| 1.25 | 7.52 ± 0.75 |
| 1.11 | 9.51 ± 0.95 |
| 0.98 | 10.52 ± 1.05 |
| 0.91 | 7.10 ± 0.71 |
| 0.86 | 7.59 ± 0.76 |

According to another embodiment, alone or in combination with the foregoing or following embodiments, the polymer in the membrane comprises at least 68% of carbon and at least 5% of hydrogen. Additionally, in a more particular embodiment, the polymer has oxygen in a percentage below 20%.

According to a preferred embodiment, the selective absorption membrane of the invention has only one of its sides coated by the nanoporous material of the invention.

According to another aspect, the instant invention provides a process for manufacturing a nanoporous material membrane comprising the steps of:
a) providing a substrate inside a plasma reactor, being said substrate selected from a metallic mesh, a polymeric fibers mesh, or a natural fibers mesh,
b) feeding the plasma reactor with a carbon source selected from the group consisting of acetylene, methane, ethane, benzene, and combinations thereof, and
c) performing and maintaining a discharge of radiofrequency with a power in the range of 10-550 W at a pressure equal to or higher than 1 mbar.

Any of the carbon sources of step b) or combinations thereof can be combined with an inert gas.

In a preferred embodiment of the process for manufacturing the nanoporous material membrane of the invention, the carbon source is acetylene.

In a preferred embodiment, the radiofrequency discharge is kept at a power of 25 W and the working pressure is 2 mbar.

In another preferred embodiment the radiofrequency discharge is kept at 45 W and the working pressure is 5 mbar.

In yet another preferred embodiment the radiofrequency discharge is kept at 210 W and the working pressure is 7 mbar.

In an embodiment the plasma reactor is a reactor of flat geometry.

In another embodiment the plasma reactor is a reactor of cylindrical geometry.

According to another embodiment, alone or in combination with the foregoing or following embodiments, the process for manufacturing the nanoporous membrane of the invention is performed with a continuous bias voltage between −3 V and −450 V, more preferably, −5 V, or −10 V.

In one embodiment the discharge time is between 5-30 minutes. The process can be carried out for longer periods of time, even hours, by providing cooling means or by interrupting the discharge at intervals of between 2 and 25 minutes, such as for example for 5 minutes, keeping the flow of the carbon source.

In other embodiments the substrate located in the interior of the reactor is placed on a grounded electrode, is placed on an insulator electrode, is placed on or around the power electrode, is placed on the walls of the reactor, or combinations thereof.

More specifically, when the substrate is a metallic mesh, said substrate must be placed on top of a polarizable material such as glass, teflon, fabric of synthetic polymeric fibers, fabric of natural fibers, etc.

The substrate can also be for example a fabric of synthetic polymeric fibers or fabric of natural fibers.

According to a particular embodiment a previous step is envisioned in which vacuum is produced within the plasma reactor. In this way, before the injection of reactive gas the baseline pressure within the chamber is brought to between 10⁻¹ and 10⁻⁶ mbar, preferably 10⁻² mbar. The baseline pressure (before the pressure at which the discharge starts) is not critical, although it must be enough as to guarantee an oxygen level below 5% within the chamber.

According to yet another aspect, the invention relates to a process for removing hydrophobic compounds from its mixtures in water, said process comprising contacting the side coated by nanoporous material of the selective absorption membrane of the invention which has only one of its sides coated by the nanoporous material of the invention, with a mixture of hydrophobic compounds and water.

According to one embodiment, in the process for removing hydrophobic compounds from its mixtures in water of the invention, the hydrophobic compound(s) are organic compounds immiscible in water. According to another embodiment, alone or in combination with the foregoing or following embodiments, the hydrophobic compound(s) are oils or greases of mineral, vegetable or animal origin. In another preferred embodiment the hydrophobic compound(s) are paraffins, oleffins, petroleum or its derivatives, or aromatic compounds such as benzene, naphtalene, anthracene and derivatives.

In another embodiment of the process for removing hydrophobic compounds from its mixtures in water of the invention, the membrane separates two compartments: a first compartment, on the side of the membrane that is coated by nanoporous material and wherein the mixture of water and hydrophobic compounds is located; and a second compartment on the side of the membrane which is not coated by nanoporous material, which receives the hydrophobic compounds once these have been separated from the water.

The selective absorption membrane of nanoporous material of the instant invention as well as the process for removing hydrophobic compounds from their water mixtures, have application in recovery of crude oil in spillages in salt water or freshwater, recovery of hydrocarbons in oil-water separators (API or similar), separation of free hydrocarbons and/or oils in water, and can be used in oil skimmers increasing the percentage of hydrocarbon recovery. The selective absorption membrane and the method also have application in recovery of vegetable oils in seed processing facilities. They also have application in conditioning of effluents for discharge into water bodies or re-usage of waters in internal cooling systems of refineries; as filters for retaining hydrocarbons for injection water in secondary oil recovery. They also have application treatment plants for hydrocarbon production water. They also have application in separator tanks and skimmers in oil refineries.

In summary, the selective absorption nanoporous material membrane of the invention is provided in the form of cloths highly absorbent of hydrocarbons and mineral or vegetable oils, that is to say, as oleophilic mats.

The selective absorption membrane of the instant invention is hyper-hydrophilic and oleophilic, only allowing permeation of hydrocarbons and mineral and vegetable oils. The proposed application has advantages relative to the existing systems as it increases the efficiency of some of the hydrocarbon/water separation systems currently used in the oil industry as skimmers and filters for retaining hydrocarbons.

The selective absorption membrane of the invention can be re-used at least three times. Its ability for acting as selective membrane allows not only recovery of the hydrocarbon, but also maximizes the absorption power when the membrane is used as part of an absorbing mat, since as a result of the fabric structure, the thicker the fabric, the larger the absorbing ability for a same amount of deposited material.

### BRIEF DESCRIPTION OF THE FIGURES

FIG. 1 is an outline of a plasma reactor of flat geometry as used for synthesizing the materials as explained in Example 1.

FIG. 2 shows two pictures of the nanoporous material in flakes as it is obtained from the reactor after depositing according to Example 1.

FIG. 3A shows filed-emission scanning (FE-SEM) images and FIG. 3B shows transmission electron microscope images of the material obtained according to Example 1.

FIG. 4 illustrates (A) the volume and (B) total pore area contribution for each pore class for the material as obtained from the reactor according to Example 1 (second and last columns of Table III).

FIG. 5 shows the nanoporous material deposited on a disc-shaped glass substrate, obtained as described in Example 3.

FIG. 6 outlines a plasma reactor of cylindrical geometry.

FIG. 7 shows an image of part of a fabric substrate showing (a) an uncoated area and (b) an area coated with the nanoporous material according to the process followed in Example 4.

FIG. 8 shows scanning electron microscope images of the nanoporous material deposited on a silicon substrate, obtained according to Example 4.

FIG. 9 shows scanning electron microscope images of the nanoporous material deposited on a silicon substrate, obtained according to Example 5.

FIG. 10 shows optical images of deposits of nanoporous material on glass substrate at different discharge times, as described in Example 5.

FIGS. 11A and 11B show the contact angle of (A) a distilled water drop and (B) an oil drop on a glass disc coated with the nanoporous material of the invention.

FIG. 12A shows the contact angle of a distilled water drop and FIG. 12B shows the contact angle of an oil drop on a glass disc coated with the nanoporous material of the invention and treated with UV radiation at a power of 4000 μW/cm² for 10 minutes.

FIG. 13A shows the UV-visible spectrum of the material of the invention untreated and FIG. 13B shows the UV-visible spectrum of the material of the invention treated with UV radiation at a power of 4000 μW/cm² for 10 minutes.

FIG. 14 shows the FTIR spectrum of the material of the invention exposed to UV radiation at a power of 4000 μW/cm² for 10 minutes and the FTIR spectrum of the material of the invention untreated.

FIG. 15 shows the ¹H-NMR spectrum of the nanoporous material of the invention.

FIG. 16 shows a metallic mesh (a) before and (b) after depositing of the material of the invention for a time long enough as for completely coating the mesh.

FIG. 17 shows a field emission scanning electron microscopy image (FE-SEM) of the material of the invention deposited on a metallic mesh.

FIG. 18A shows SEM images of the nanoporous material deposited on a silicon substrate for a discharge time of 1 min on the left, and the corresponding Scotch test results on the right and FIG. 18B shows the same for a discharge time of 30 seconds.

FIG. 19 shows an outline of the cell for the selective absorption assay described in Example 12.

FIG. 20 shows an electron microscope image of a material deposited at constant pressure of 0.12 mbar and RF power kept at 50 W, with a gas influx of 20 SCCM.

FIG. 21 shows the water contact angle of a material deposited under constant pressure at 0.12 mbar and RF power kept at 50 W, with a gas influx of 20 SCCM.

FIG. 22 shows (a) a macroscopic view and (b) an electron microscope image of a material deposited on a metallic mesh at a pressure kept constant at 0.4 mbar, RF power kept at 211 W, and bias voltage at −650 V.

FIG. 23 shows a glass substrate coated with a material deposited at a pressure kept constant at 0.4 mbar, RF power kept at 211 W, and bias Voltage at −650 V.

FIG. 24 shows the contact angle of (a) water and (b) oil of a material deposited at a pressure kept constant at 0.4 mbar, RF power kept at 211 W, and bias Voltage at −650 V.

### DETAILED DESCRIPTION OF THE INVENTION

The properties of nanoporous materials, such as adhesive strength, hydrophobicity, absorption/adsorption ability, possibility of being functionalized with a given chemical group, reactivity, number of atoms on surface, ability of storing small molecules, controlled and specific functionalization for a given use, etc., are typically the result of the combination of their chemical composition and molecular architecture with their three-dimensional structure at a nanometric scale, which defines the porosity properties of the material. In the case of nanoporous materials formed by aggregated nanometric particles obtained by plasma polymerization, these aspects are determined both by the reaction gases used and by the conditions under which the depositing process is carried out. Moreover, in that kind of materials the three-dimensional structure and the material porosity are determined mainly by the size of the constituent nanoparticles.

For example, Wei Dai and colleagues (op. cit.) showed that at depositing pressures of 200 mTorr or less deposition of the polymer takes place homogeneously, originating materials with a relatively smooth surface. At depositing pressures of between 300 and 500 mTorr, however, the polymer is deposited as carbon nanoparticle networks, originating a nanoporous material in which the nanoparticles have a diameter of about 30-50 nm. In patent application US 2014/0116936 A1, however, the same research team discloses that when pressure exceed 500 mTorr (0.6666 mbar), there is a risk that the plasma would become unstable, hindering the formation of the nanoporous material. In the same document, the authors mention that porosity increases and the radius of the nanoparticles decreases when CF₄ is added to the acetylene used as primary carbon source. In these conditions the authors obtained better defined crosslinking and bridges, formed by nanoparticles of about 5 nm of diameter. Furthermore, with the addition of CF₄ to the reactor's inflow, the obtained materials were predictably more hydrophobic.

Dai and colleagues report a water contact angle of about 148° for the material they obtained without fluorine addition (estimate from figure S3A in Dai et al. 2012). However, when the conditions disclosed by Dai and collaborators both in the scientific publication and in patent application US 2014/0116936 A1, the instant inventors obtained a material wherein the water contact angle was of about 52° (See example 15). Additionally, yield in the polymer production was relatively low, and coating ability and adherence of the material were limited when deposited on a substrate.

Surprisingly, using depositing pressures well above those of the prior art, at which the skilled person would have expected that plasma depositing would become unstable, the instant inventors obtained a highly hydrophobic nanoporous material, with high specific surface area, with a water contact angle greater than 130°, with excellent coating ability, and with good adherence when deposited on a substrate. Unexpectedly, contrary to the material disclosed in Dai et al. (op. cit) and in patent application US 2014/0116936 A1, the nanoporous material of the instant invention achieves an increased specific surface are when increasing the size of the constituent particles, which have diameters of up to 200 nm (and even larger, although particles with diameter larger than 200 nm do not exceed 3% of the total number of particles) much larger than the particles of around 30 nm reported by Dai and colleagues for their material obtained without CF₄ addition.

Notably, of the nanoparticles that form the material of the instant invention, the larger ones are even larger than the clusters in the material obtained by Dai and colleagues (which have a maximum diameter of 50 nm). Accordingly, the clusters of particles in the material of the instant invention also have a larger diameter than those of the prior art materials, with a maximum diameter of at least 200 nm.

Advantageously, according to the instant invention, the specific surface increase does not result from CF₄ addition to the gas inflow. Besides simplifying the production process, this avoids the risk that generation of different ionic fluorine species during the depositing process results in fluorhydric acid, which is highly corrosive and whose presence in the reactor would cause countless operative and safety problems.

When plasma polymerization is carried out, the reactor feeding gas or gas mixture are transformed into plasma, in which all ionic species that such mixture can form are theoretically present. These ionic species react between them and deposit as a polymer which, opposite to polymers obtained by the classic linking of monomers, does not have a chemical structure in which a same unit is repeated, but the plasma polymer forming units can vary within certain limits.

In the instant invention, the polymer forming the nanoporous material has a spatial conformation of open network comprising the repetitive hydrocarbon structure with isolated double bonds of formula I:

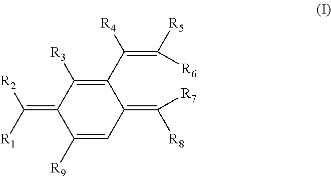

wherein R1-R9 are molecular groups which bind with other structures of formula I, each independently selected from H, (C₁₋₅) alkylene- or (C₆₋₁₀) cycloalkylene-(C₁₋₅) alkylene-; wherein the alkylene groups can be saturated or have one or more carbon-carbon double bonds, wherein the groups cycloalkylene have one or more carbon-carbon double bonds, and wherein one or more carbon atoms of the alkylene and cycloalkylene chains can be substituted by a —O— bridge or by —OH.

In the context of the present invention, the expression “open network” designates a hydrocarbon structure containing micropores, that is, in the nanoporous material of the instant invention the smaller pores are defined mostly not by the spaces between nanoparticles, but are mostly “intra-particle” pores defined by open areas in the molecular network forming the polymer. In fact, the intra-particle pores in the aggregates formed by the smaller particles (around 8 nm in diameter) could generate micropores in the order of 4-5 nm in diameter, and consequently micropores under 5 nm in diameter in the nanoporous material of the instant invention would be exclusively intra-particle. Presence of these intra-particle pores allows grinding the material to a powder constituted mostly by disaggregated nanoparticles and by aggregates formed by a few nanoparticles in which the intra-particle pores remain unaltered. That is, presence of the smaller micropores is preserved even when the material original architecture has been completely modified. This feature is advantageous in many applications, such as when it is desirable or necessary to use a powdered material as catalyst carrier or in general for absorbing/adsorbing small molecules such as heptanes, octanes or benzene.

The material of the invention in powder form can be also obtained by scraping the material deposited on the reactor chamber walls and on the electrodes when no substrate has been introduced into the reactor. That is, the nanoporous material of the invention is always deposited as nanoparticles aggregations: when a substrate is placed inside the reactor (for example, a metallic mesh, a sheet of a suitable material, a fabric, etc.) said aggregations are deposited as a coating on the substrate. Otherwise, in absence of a substrate, depositing takes place on the walls of the reactor chamber and on the electrodes, and scraping of the deposited material allows obtaining a powder constituted by the material of the invention.

Intra-particle micropores presence is in part responsible of the large specific surface area of the nanoporous material of the instant invention, wherein pores of radius equal or less than 2 nm contribute at least 60% of the total pore area (or porosity) measured according to the BJH method (Barret, Joyner & Halenda). In a particularly preferred embodiment, pores of radius equal or less than 2 nm contribute with 63% of the total pore area of the material, which makes the material particularly suitable for absorbing/adsorbing small molecules, such as heptanes, octanes or benzene.

The carbon source used for synthesizing the polymer which makes the nanoporous material of the instant invention can be for example acetylene, methane, ethane, benzene, or combinations thereof, and the resulting polymer can be formed exclusively or essentially exclusively by carbon and hydrogen.

By the expression “essentially exclusive” must be understood that the polymer can also comprise negligible or trace amounts of other elements such as oxygen or nitrogen. However, according to the variations contemplated in the chemical structure of the polymer, it can be formed also by significative amounts of oxygen. For example, in a particular embodiment, the polymer comprises between 68 and 84% of carbon, between 5 and 7% of hydrogen, and oxygen in a percentage lower than 20%, such as under 18%. In an even more particular embodiment, the nanoporous material of the invention is formed by a polymer comprising 76% of carbon, 6% of hydrogen, and 17% of oxygen. The oxygen atoms can be present, for instance, forming terminal hydroxyls.

The polymer forming the nanoporous material of the invention is in the form of spherical nanoparticles aggregated with each other. The size of the nanoparticles depends upon the specific conditions under which depositation is carried out, which can vary within certain ranges, as will be explained below. In some embodiments the nanoparticle size is more or less homogeneous, while in other embodiments the nanoparticle size varies within a range spanning two orders of magnitude, such as about 8 to about 200 nm in diameter.

In all cases, however, at least 40% of the nanoparticles, and in some embodiments at least 50% of the nanoparticles, such as at least 60%, are larger than 50 nm in diameter. This nanoparticle size distribution is the critical aspect defining the architecture of the material of the invention at a nanometric scale, and with it many of its properties.

The nanoporous material of the instant invention has a high specific surface area, which is a desirable feature in most applications of nanoporous materials. When measured by the BET method (Brunauer-Emmett-Teller), the specific surface area of the material of the instant invention is about 141 and 173 m²/g. In a particular embodiment, the nanoporous material of the instant invention has a specific surface area of 157 m²/g measured by the BET method.

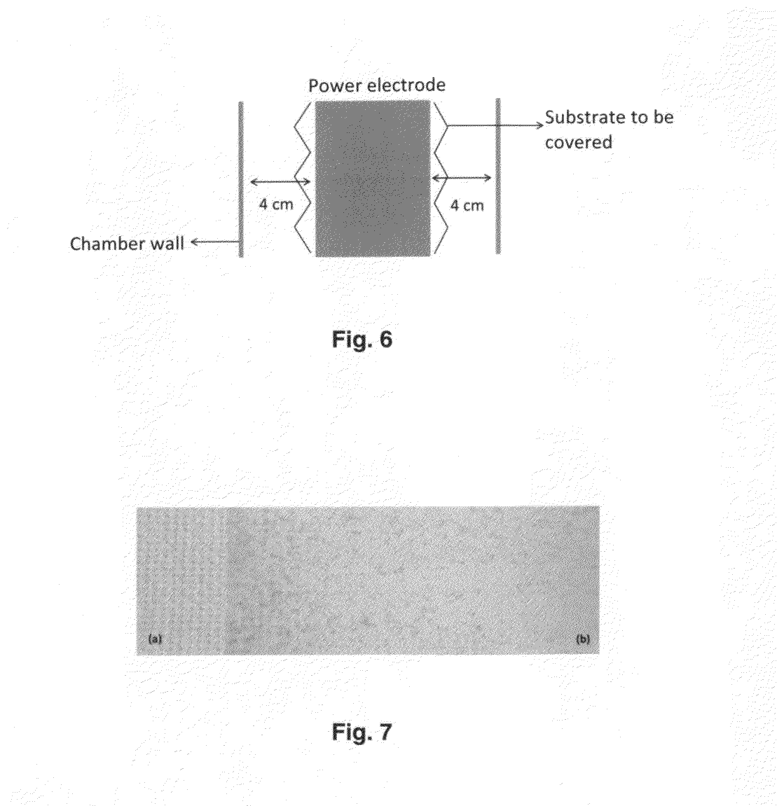

A particularly advantageous feature of the nanoporous material of the invention is its high hydrophobicity, as revealed by the water contact angle, which is higher than 130° (see FIG. 6). This feature, as well as its high specific surface area, makes the nanoporous material of the invention particularly useful for removing from water compounds which are immiscible in water, such in oil or oil derivatives spillage remediation, or in filtering and purification of water.

Surprisingly, the nanoporous material of the invention absorbs ultraviolet radiation in one hand, and in the other hand changes its hydrophobicity when subjected to ultraviolet radiation, in such a way that the material becomes hydrophilic after a long enough exposure, at the same time that the non-exposed material keeps its ability to absorb hydrophobic compounds. The exposure time required for changing the wettability of the material will depend on the radiation intensity. For instance, at a power of 4000 μW/cm², exposure for 5 minutes will be enough for the material to become hydrophilic. Lower radiation powers will require a longer exposure time, and vice versa. This change in the wettability of the material only affects the surface exposed to radiation, and hence the material which is not exposed on surface receiving the ultraviolet radiation will remain hydrophobic. As an example, radiation can be applied to only one side of a sheet of the material of the invention, in such a way that a sheet with one hydrophobic side and one hydrophilic side is obtained.

According to one embodiment, a membrane of nanoporous material can be obtained by plasma polymerization of a hydrocarbon compound, depositing the reaction material on a metallic, ceramic, or polymeric mesh, in such a way that the material of the invention closes the openings of the mesh and completely coats it, and as a result the mesh is included into the sheet. By treating one of the sides of the sheet with ultraviolet radiation, a material where one side is hydrophobic and the other side is hydrophilic is obtained. This kind of mesh with both faces coated has application for instance in cosmetics or medicine (such as in injuries protection or covering), with the more hydrophilic side having more affinity for the skin and the more hydrophobic side facing outwards and repealing water.

Its ability of absorbing ultraviolet radiation allow the material of the invention to be advantageously used as ultraviolet radiation protection per se (for example, being deposited on the surface whose protection is desired) or as additive in compositions for protecting against ultraviolet radiation, such as paints, waterproofing products, varnishes, and the like. Moreover, the change in hydrophobicity when absorbing said radiation, make the material of the invention particularly interesting as additive in cosmetic compositions such as sunscreens, since when exposed to the sun for long enough the material of the invention becomes hydrophilic and thus is easier to wash it out of the skin. When used as additive in these or other kinds of compositions, the material of the invention will be previously transformed into powder with a suitable particle size.

The nanoporous material of the invention has a glass-liquid transition equal to or higher than 50° C. and a thermal stability equal to or higher than 200° C.

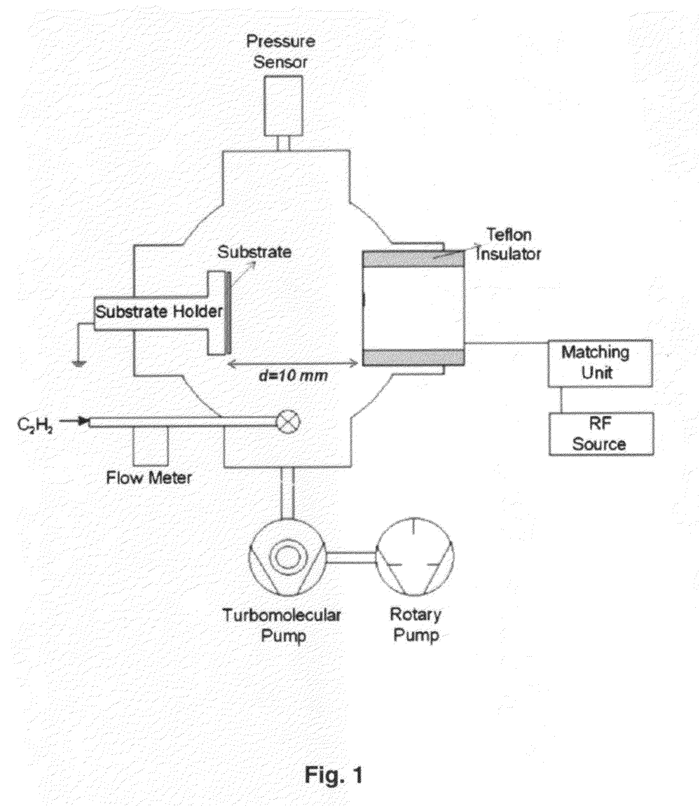

According to one embodiment, the nanoporous material of the invention is obtained by plasma polymerization of a hydrocarbon compound selected from the group consisting of acetylene, methane, ethane, benzene, and combinations thereof. The carbon source is preferably acetylene. The plasma reactor is preferably a vacuum chamber such as a stainless steel chamber with two flat electrodes parallel to each other inside (flat configuration reactor). The electrodes can be disc-shaped stainless steel plates. An outline of a reactor of flat configuration is shown in FIG. 1. One of the electrodes is connected to a radio frequency supply (RF 13.56 MHz, 600 W) through an impedance coupling unit, and the other electrode is grounded.

According to a first step the pressure inside the chamber is brought to a baseline pressure of between 10⁻¹ y 10⁻⁶ mbar, preferably 10⁻² mbar. The baseline pressure (before the pressure at which the discharge starts) is not critical, and similar results were obtained when the Examples below were repeated using baseline pressures of 10⁻¹ and 10⁻² instead of 10⁻⁶ (results not shown), although the baseline pressure must be enough for ensuring an oxygen level within the chamber below 5%.

The introduction of hydrocarbon gas, preferably acetylene, is made at a flow rate that is enough for keeping the depositing pressure within the range from 1 to 10 mbar, particularly 1 mbar, 2 mbar, 3 mbar, 4 mbar, 5 mbar, 6 mbar, 7 mbar, 8 mbar, 9 mbar, 10 mbar and all intermediate values. Preferably, the depositing pressure is 2 mbar. During the depositing process, the RF power is kept within a range of 20-550 W, preferably at 25 W.

A suitable reactor for performing a plasma polymerization according to the instant invention comprises a reaction chamber which has a capacitive coupling system with at least one electrode fed by a radiofrequency source and at least one grounded electrode. A suitable reaction chamber is evacuable and is able to keep conditions that produce a plasma treatment. That is, the chamber provides an environment which allows control of pressure, flow of different inert and reactive gases, voltage supply to the power electrode, electric field intensity through the ion sheath, formation of a plasma containing reactive species, ion bombardment intensity, and rate of depositing of a film from the reactive species, among other parameters. Aluminum is a preferred material for the chamber since it has a low production of cathode sputtering, meaning that very little contamination occurs from the chamber surfaces. Nevertheless, other materials that are also suitable can be used, such as graphite, cupper, glass or stainless steel.

The electrode system can be symmetrical or asymmetrical. According to the instant invention, asymmetrical electrodes are preferred. In general, it is preferred that the power electrode is smaller as the direct current polarization on a smaller grounded electrode would deviate to ground. The power electrode can be cooled, for instance by means of a water cooling system. This is particularly important when obtaining the material as a powder is intended, as otherwise the polymer powder deposited on the power electrode tends to burn out.

It is important to note that any reactor configuration allows obtaining the nanoporous material or the coated substrates (included the selective absorption membranes) of the invention.

Suitable pressure and power are determined depending on the distance between electrodes and on the reactor's configuration. For example, in the case of a flat geometry reactor with electrodes separated by 5 cm, the optimal power is 25 W and the optimal pressure is 2 mbar, while for electrodes separated by 8 cm, the optimal power is 45 W and the optimal pressure is 5 mbar. In the case of a reactor of cylindrical geometry, for an electrode separation of 4 cm for example, the optimal parameters are a pressure of 4.5 mbar and a power of 35 W.

The nanoporous material is deposited on the electrodes and in the reactor chamber walls, as well as on the substrate that is eventually introduced in the chamber, for example when manufacturing the membranes or sheets of the invention. In this was, for example, the nanoporous membrane of the invention is obtained by placing a suitable substrate within the reactor and then carrying out the polymer depositing. The substrate can be placed on the electrode connected to the radiofrequency source, on the grounded electrode, or not touching any of the electrodes but interposed between them, although it is preferred that the substrate is on the electrode connected to the radiofrequency source, in particular when the substrate is fabric. Moreover, when the reactor has a cylindrical configuration, placing the substrate on the electrode connected to the radiofrequency source allows for depositing of a larger amount of polymer.

During the depositing process, the radiofrequency power is kept within a range of 20-550 W, preferably at 25 W, the power varying if the distance between electrodes changes.

According to a preferred embodiment, the nanoporous material membrane of the invention is obtained by plasma polymerization of acetylene injected into a reactor which has two flat electrodes parallel to each other (flat configuration), keeping a pressure of 2 mbar and a discharge power of 25 W. Depositing of the polymer is carried out on a substrate, such as a metallic mesh or a polymeric material mesh, being the substrate preferably placed on top of an electrode. In the case of a metallic mesh, said mesh is placed on top of a polarizable material such as glass, Teflon, fabric of synthetic polymeric fibers, fabric of natural fibers, etc.

In another embodiment of the invention, the substrate is a fabric of synthetic polymeric fibers or fabric of natural fibers.

According to an additional preferred embodiment, the nanoporous material membrane of the invention is obtained by plasma polymerization of acetylene injected into a reactor of cylindrical configuration, wherein the wall of the chamber is grounded and a cylindrical electrode disposed centrally within the chamber is connected to the radiofrequency supply by means of an impedance coupling unit. An outline of such reactor can be seen in FIG. 1B. For example, the gas is introduced at a flow rate enough as for keeping the pressure at 4.5 mbar, keeping a discharge of 45 W, although other pressures and discharge power values also result in depositing of the material of the invention, such as for example a pressure of 7 mbar and a discharge power of 210 W. The polymer deposition is made in this case on a substrate, preferably a metallic or polymeric material mesh, being the substrate placed preferably surrounding the power electrode on an electrode. According to an alternative preferred embodiment the substrate is in contact with the walls of the grounded chamber. Even more preferred, the metallic mesh is placed on top of a polarizable material such as glass, Teflon, fabric of synthetic polymeric fibers, fabric of natural fibers.

Depositing of the polymer at is done at pressures of at least 1 mbar, such as 2 mbar, 5 mbar, 7 mbar, which are much higher than pressures deemed “safe” by the skilled person regarding plasma stability. Effective depositing at such a high pressure is achieved using a radiofrequency discharge, for example capacitive coupling radiofrequency, with a power in the range of 20-550 W, preferably in a range of 25 W-210 W. According to the process for producing the nanoporous material of the invention, for a given geometric configuration, at a same depositing pressure, different power values and a given bias voltage (generated in the chamber as a consequence of the geometry and the other parameters) will cause changes in the particle size and homogeneity, although always within the values defining the material of the invention. For example, at a pressure of 2 mbar, the nanoporous material obtained using a 25 W power has a large variation in the size of the constituent nanoparticles (8-100 nm in diameter).

The process for producing the nanoporous material of the invention allows obtaining significative amounts of the material. For example, amounts of 0.17 g/m² or more can be obtained keeping the radiofrequency discharge for 10 minutes and employing a power of 25 W and a pressure of 2 mbar. In general terms, the yield increases as a function of the depositing pressure, with higher yields at higher pressures.

The invention also relates to a process for removing hydrophobic compounds from its mixtures in water, said process comprising contacting the side coated by nanoporous material of the selective absorption membrane of the invention which has only one of its sides coated by the nanoporous material of the invention, with a mixture of hydrophobic compounds and water. In a particular embodiment of the process of the invention, the membrane separates two compartments, a first compartment on the side of the membrane that is coated by nanoporous material and wherein the mixture of water and hydrophobic compounds is located; and a second compartment on the side of the membrane which is not coated by nanoporous material, which receives the hydrophobic compounds once these have been separated from the water.

In the context of the instant invention, the term “compartment” does not make reference necessarily to a confined volume, but refers to a space capable of containing the mixture of water and hydrophobic compounds, or the hydrophobic compounds which have been separated from said mixture. Thus, if the separation method of the invention is carried out within a cell divided by the selective absorption membrane of the invention, the compartments will be each of the resulting partitions in which the cell is split when the membrane is used as a divider. However, if the separation process is carried out in a natural or artificial water body affected for example by a hydrocarbon spillage, the membrane can be used as a barrier for defining compartments in the environment, wherein the first compartment will be the contaminated water body, and the second compartment will be the place where hydrocarbon accumulation takes place once it has been separated from water.

In the context of the instant invention, it should be understood that “hydrocarbon mixtures in water” comprise both oil-in-water and water-in-oil emulsions, as well as hydrocarbons in dissolved phase.

The nature, scope, and way to put into practice the instant invention according to all its aspects will be best understood from the examples below. However, it must be understood that these examples are given for an illustrative purpose only, and in no way limit the object of the invention, whose scope is exclusively defined by the appended claims.

### EXAMPLES

### Example 1

For polymerization, a radiofrequency (RF) plasma reactor consisting in a stainless steel vacuum chamber inside which there were two flat electrodes parallel to each other (flat configuration) was used. The electrodes were flat disc-shaped stainless steel plates of 89 mm in diameter separated 10 mm from each other. An outline of the reactor (flat configuration) can be seen in FIG. 1. The chamber was brought to a baseline pressure of 10⁻⁶ mbar, one of the electrodes was connected to the radiofrequency supply (RF13.56 MHz, 600 W) by means of a impedance coupling unit, and the other electrode was grounded.

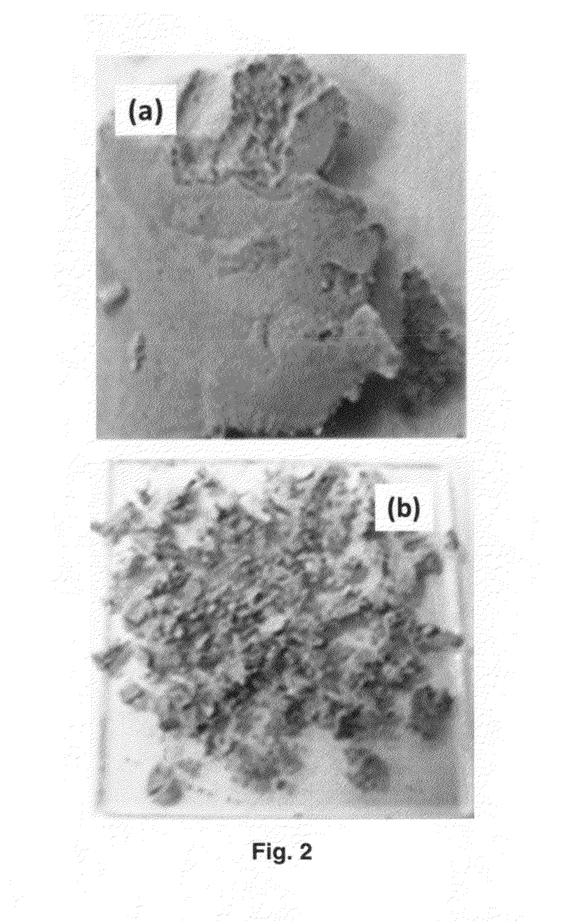

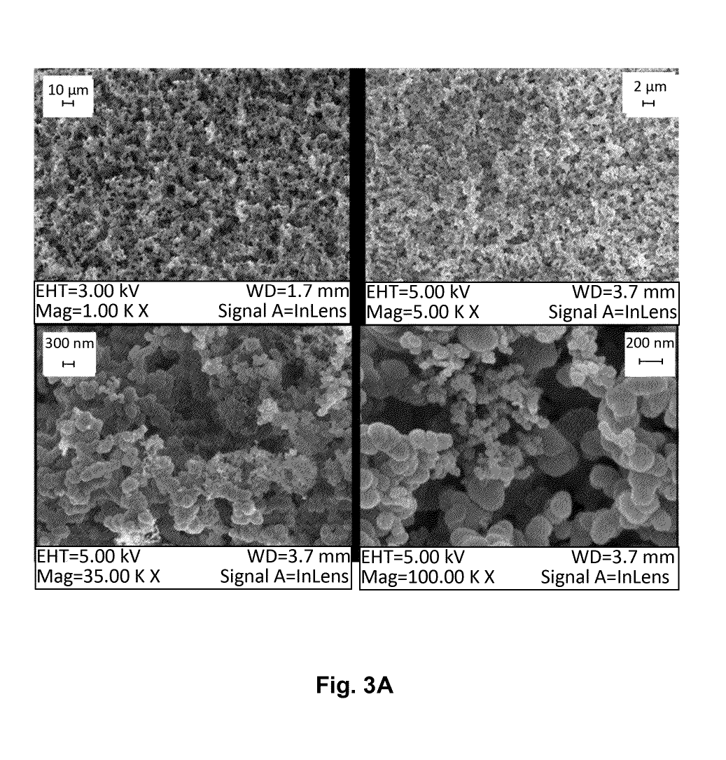

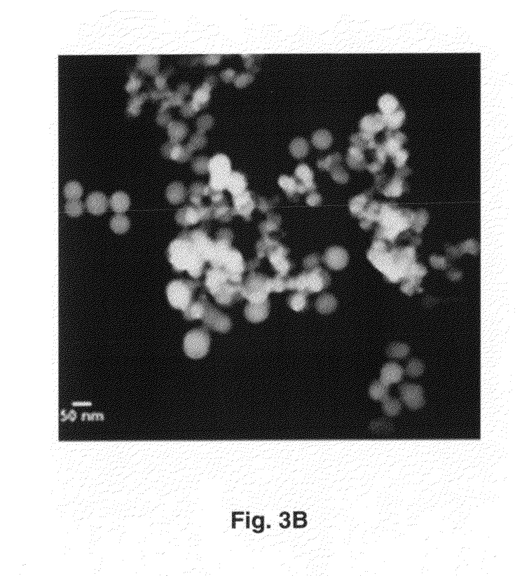

Commercial grade acetylene gas was introduced into the reactor at a flow rate of 150 SCCM, enough for maintaining the depositing pressure at 2 mbar. During the depositing process, the RF power was kept at 25 W and a bias voltage of −10 V. The discharge was kept for 5 minutes. This resulted in a yellow material deposited on the grounded electrode and in the walls of the reactor. The scales of material as it comes out of the reactor are shown in FIG. 2. The analysis by field emission scanning electron microscopy (FE-SEM) showed that the material was deposited in the form of a nanoporous material constituted by nanoparticles aggregated with each other in which the particle aggregations formed a network or lattice which defined the pores at a manometric scale (FIG. 3). The size of the nanoparticles was calculated by analyzing electron microscope images with the open source software ImageJ (http://imagej.net) which allows counting and measuring the particles. The percentages were graphed as histograms, showing that the polymer nanoparticles had a radius between 8 and 200 nm.

Porosity of the material obtained by 10 replicates under the same conditions described above was analyzed by the BET (Brunauer-Emmett-Teller) and BJH (Barrett, Joyner & Halenda) methods. The data for the material in flakes as it comes out of the reactor are shown in Tables I and III. Tables II and IV show the data for the same material after grinding it by hand in a mortar for 5 minutes until a fine powder was obtained. The porosity data of Tables III and IV were obtained by the BJH method.

TABLE I
FLAKE SAMPLE

| | | Mean pore | |
|---|---|---|---|
| | Surface area | volume | Mean pore radius |
| Method | m²/g | cm³/g | Å |
| BET | 157 | 0.2855 | 72.74 |

Distribution by pore size range

| | | | Contribution to total |
|---|---|---|---|
| | | Total pore | pore area by pore |
| | Pore area | volume | class |
| BJH (8.5 Å-1500 Å) | m²/g | cm³/g | % |
| Micropores (0-20 Å) | 63.74 | 0.0393 | 62.9 |
| Mesopores (20-500 Å) | 35.78 | 0.1412 | 35.30 |
| Macropores (>500 Å) | 1.77 | 0.0711 | 1.74 |

TABLE II
POWDER SAMPLE

| | | Mean pore | |
|---|---|---|---|
| | Surface area | volume | Mean pore radius |
| Method | m²/g | cm³/g | Å |
| BET | 163.6 | 0.2153 | 52.63 |

Distribution by pore size range

| | | | Contribution to total |
|---|---|---|---|
| | | Total pore | pore area by pore |
| | Pore area | volume | class |
| BJH (8.5 Å-1500 Å) | m²/g | cm³/g | % |
| Micropores (0-20 Å) | 47.17 | 0.0300 | 61.00 |
| Mesopores (20-500 Å) | 29.20 | 0.1037 | 37.77 |
| Macropores (>500 Å) | 0.95 | 0.0332 | 1.23 |

TABLE III
FLAKE SAMPLE

| | | | | | Contribution |
|---|---|---|---|---|---|
| Pore mean | Pore | Accumulated | Pore | Accumulated | to total pore |
| radius | volume | pore volume | area | pore area | area |
| Å | cm³/g | cm³/g | m²/g | m²/g | % |
| 1145.4 | 0.0358 | 0.0358 | 0.62 | 0.62 | 0.62 |
| 619.2 | 0.0354 | 0.0711 | 1.14 | 1.77 | 1.13 |
| 420.7 | 0.204 | 0.0915 | 0.97 | 2.74 | 0.96 |
| 236.7 | 0.0328 | 0.1244 | 2.78 | 5.51 | 2.74 |
| 154.0 | 0.0175 | 0.1419 | 2.28 | 7.79 | 2.25 |
| 113.2 | 0.0120 | 0.1539 | 2.12 | 9.91 | 2.09 |
| 89.1 | 0.0089 | 0.1628 | 1.99 | 11.90 | 1.96 |
| 73.5 | 0.0072 | 0.1700 | 1.96 | 13.86 | 1.93 |
| 61.3 | 0.0071 | 0.1771 | 2.32 | 16.18 | 2.29 |
| 53.5 | 0.0043 | 0.1814 | 1.61 | 17.79 | 1.59 |
| 44.5 | 0.0076 | 0.1890 | 3.42 | 21.21 | 3.38 |
| 36.2 | 0.0064 | 0.1954 | 3.51 | 24.72 | 3.46 |
| 30.4 | 0..0069 | 0.2022 | 4.53 | 29.25 | 4.47 |
| 26.0 | 0.0051 | 0.2074 | 3.93 | 33.18 | 3.88 |
| 22.6 | 0.0050 | 0.2123 | 4.37 | 37.55 | 4.32 |
| 19.9 | 0.0046 | 0.2170 | 4.68 | 42.23 | 4.62 |
| 17.6 | 0.0043 | 0.2213 | 4.94 | 47.17 | 4.87 |
| 15.6 | 0.0042 | 0.2255 | 5.35 | 52.51 | 5.28 |
| 14.0 | 0.0042 | 0.2297 | 6.00 | 58.51 | 5.92 |
| 12.5 | 0.0048 | 0.2344 | 7.62 | 66.13 | 7.52 |
| 11.1 | 0.0054 | 0.2398 | 9.64 | 75.77 | 9.51 |
| 9.8 | 0.0052 | 0.2450 | 10.66 | 86.42 | 10.52 |
| 9.1 | 0.0033 | 0.2483 | 7.19 | 93.61 | 7.10 |
| 8.6 | 0.0033 | 0.2516 | 7.69 | 101.30 | 7.59 |

TABLE IV
POWDER SAMPLE

| Pore | | | | | Contribution |
|---|---|---|---|---|---|
| mean | Pore | Accumulated | | Accumulated | to total pore |
| radius | volume | pore volume | Pore area | pore area | area |
| Å | cm³/g | cm³/g | m²/g | m²/g | % |
| 937.3 | 0.0159 | 0.0159 | 0.34 | 0.34 | 0.44 |
| 564.6 | 0.0173 | 0.0332 | 0.61 | 0.95 | 0.79 |
| 385.8 | 0.0127 | 0.0459 | 0.66 | 1.61 | 0.85 |
| 226.0 | 0.0207 | 0.0666 | 1.83 | 3.44 | 2.37 |
| 149.8 | 0.0128 | 0.0794 | 1.71 | 5.15 | 2.21 |
| 111.0 | 0.0092 | 0.0886 | 1.65 | 6.81 | 2.14 |
| 87.8 | 0.0071 | 0.0957 | 1.62 | 8.42 | 2.09 |
| 72.6 | 0.0057 | 0.1014 | 1.56 | 9.99 | 2.02 |
| 60.6 | 0.0057 | 0.1071 | 1.90 | 11.88 | 2.45 |
| 52.8 | 0.0036 | 0.1107 | 1.36 | 13.25 | 1.76 |
| 43.9 | 0.0067 | 0.1174 | 3.03 | 16.28 | 3.92 |
| 35.8 | 0.0056 | 0.1230 | 3.12 | 19.39 | 4.03 |
| 30.1 | 0.0050 | 0.1280 | 3.35 | 22.74 | 4.33 |
| 25.7 | 0.0046 | 0.1326 | 3.60 | 26.34 | 4.66 |
| 22.3 | 0.0043 | 0.1369 | 3.82 | 30.16 | 4.94 |
| 19.6 | 0.0040 | 0.1410 | 4.13 | 34.30 | 5.35 |
| 17.3 | 0.0039 | 0.1449 | 4.51 | 38.81 | 5.84 |
| 15.3 | 0.0037 | 0.1486 | 4.89 | 43.70 | 6.32 |
| 13.7 | 0.0038 | 0.1524 | 5.52 | 49.21 | 7.13 |
| 12.2 | 0.0039 | 0.1563 | 6.43 | 55.64 | 8.31 |
| 10.8 | 0.0041 | 0.1604 | 7.59 | 63.23 | 9.82 |
| 9.5 | 0.0040 | 0.1644 | 8.47 | 71.70 | 10.95 |
| 8.8 | 0.0025 | 0.1669 | 5.63 | 77.33 | 7.28 |

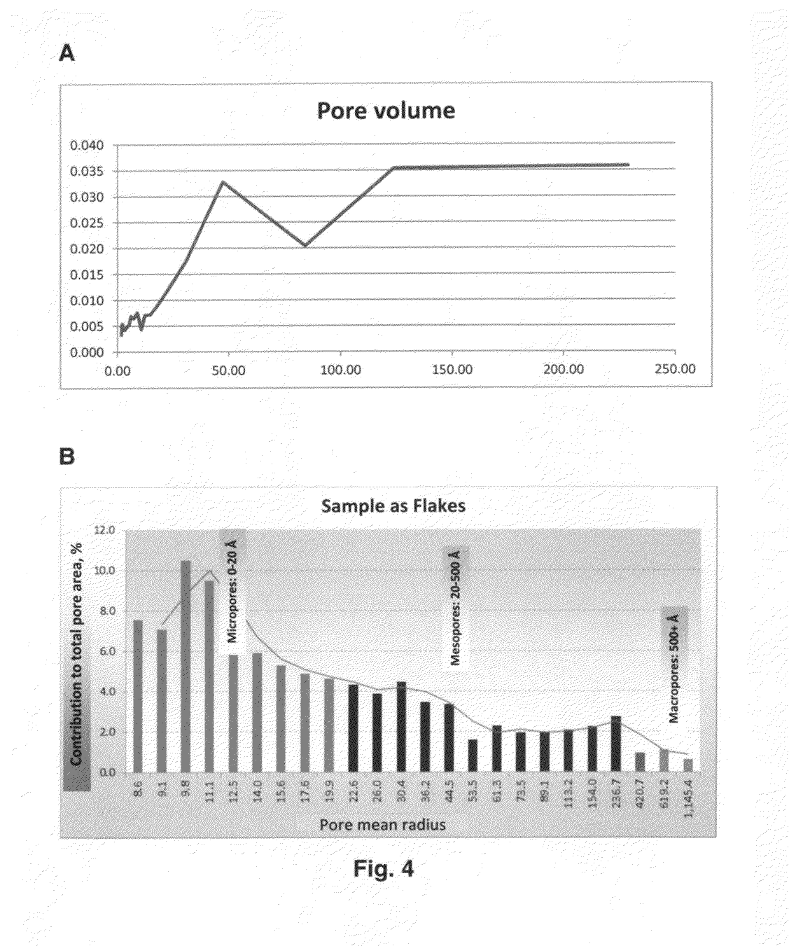

For the sample in flakes (material as it comes out of the reactor) the volume and contribution to total pore area for each pore class (second and last columns of Table III) are graphed in FIG. 4.

An elemental analysis of the obtained material was performed in an elemental analyzer Exeter Analytical CE-440 to determine the percentage of carbon and hydrogen. The microanalysis indicated that the material was formed by 76.09% of carbon and 6% of hydrogen, assuming that the 17.91% balance is oxygen, which could come from humidity in the commercial grade acetylene used or from the atmosphere.

In continuing the characterization of the obtained material, the glass-liquid transition temperature was determined by differential scanning calorimetry using a DSC 020 equipment, yielding a result of 50° C. Thermal stability, defined as the temperature at which a degradation of the polymer is first observed, was assessed with a DTG Shimatzu DTG 60, and was estimated as 220° C.

### Example 2

The same equipment and discharge parameters as in Example 1 were used, except for the baseline pressure before the discharge, which was 10⁻¹ mbar. The obtained material was the same as in Example 1. This allowed to determine that treatment before the discharge only has to guarantee a low oxygen content (under 5%), the application of vacuum not being critical.

### Example 3

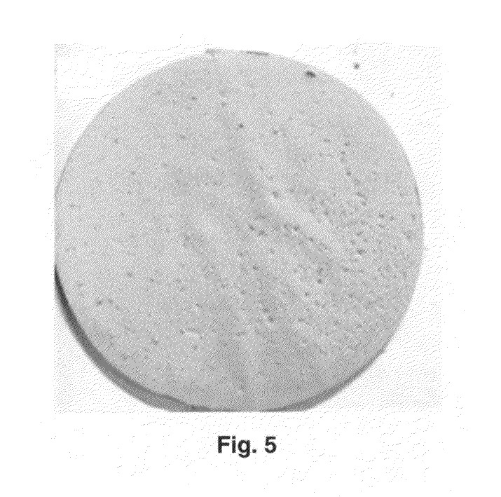

Using the same equipment and conditions as in Example 1, the plasma polymer was deposited on a disc-shaped glass substrate placed on the grounded electrode. The depositing was kept until the polymer completely coated the substrate surface (FIG. 5). The deposited material was yellow, and the microscopic analysis showed similar features to the material obtained in Example 1.

### Example 4

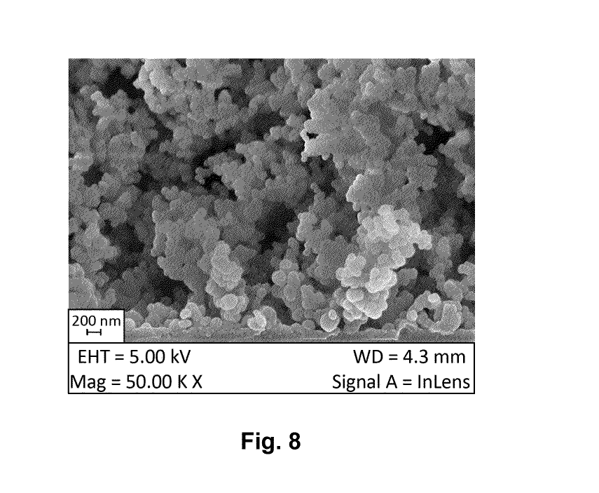

A cylindrical geometry radiofrequency (RF) plasma reactor was used. The reactor consists in a cylindrical stainless steel vacuum chamber. In this case, the chamber wall was grounded while a stainless steel electrode with cylindrical geometry 100 mm long and 80 mm in diameter was connected to the radiofrequency supply (RF 13.56 MHz, 600 W) by means of an impedance coupling unit. An outline of the reactor (cylindrical configuration) can be seen in FIG. 6. The chamber was initially brought to a baseline pressure of 10⁻⁶ mbar, then commercial grade acetylene gas was introduced into the reactor at a flow of 200 SCCM, which was enough for keeping the depositing pressure at 5 mbar. During the depositing process, the RF power was kept at 45 W and a bias voltage of −5 V. Depositing was tested on different substrates. Thus, material was deposited on the following substrates: glass, metallic mesh of 100 and 200 mesh, silicon and different kinds of fabric of polymeric synthetic fibers or of natural fibers, as well as in the walls of the reactor. The deposited material was yellow in color, and the microscopic analysis showed similar features to the material obtained in Example 1. Fabrics coated with the material obtained with the reactor of cylindrical configuration are shown in FIG. 7. Scanning electron microscope images of the material grown on silicon, using the parameters of this example, are shown in FIG. 8.

### Example 5

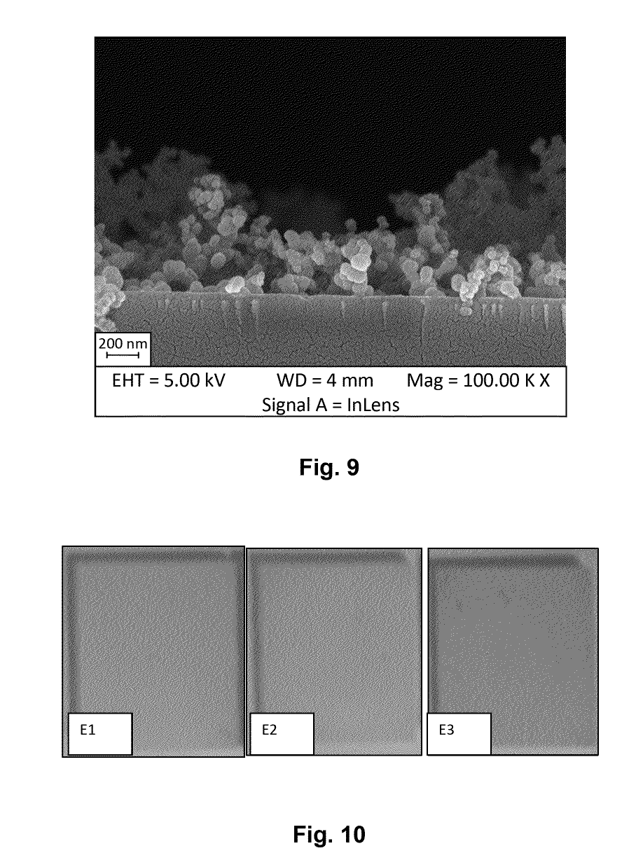

The same equipment and discharge parameters as in Example 1 were used, except that it was carried out for a discharge time as short as 10 seconds. FIG. 9 is a field emission scanning electron microscope (FE-SME) image of the material deposited on a silicon substrate wherein it can be seen that even a discharge time as short as 10 seconds results in several layers of nanoparticles as described in the instant invention. Depositing on glass using the parameters and equipment of Example 4 (cylindrical geometry) were also carried out for 10 seconds, 30 seconds, 1 minute and 5 minutes. The obtained material is the same as in Example 1. FIG. 10 shows optical images of the glass substrates obtained at different times: E1, E2 and E3 correspond to 30 seconds, 1 minute and 5 minutes of depositing time, respectively.

### Example 6

The same reactor as in Example 4 (cylindrical geometry) was used. In this case the chamber was brought to a baseline pressure of 10⁻¹ mbar. Then, commercial grade acetylene gas was introduced into the reactor at a flow which was enough for keeping the depositing pressure at 7 mbar. During the depositing process, the RF power was kept at 210 W. After 5 minutes, a yellow material deposited on the walls of the reactor and on different substrates was obtained. Glass, steel mesh of 100 and 200 mesh, silicon, and different kinds of fabric were tested as substrates. The deposited material was yellow. Microscopic and physicochemical analysis of the obtained material show similar features to the material obtained in Example 1.

### Example 7

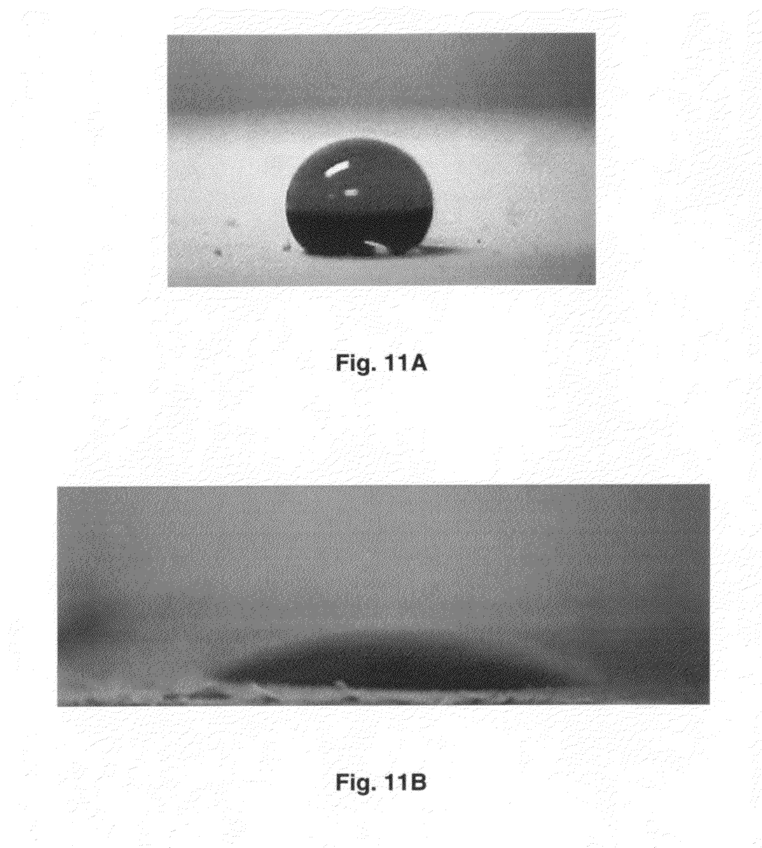

With the purpose of evaluating the hydrophobicity of the material, the contact angle of a distilled water drop placed on the coated glass disc of Example 3 was measured using a G1 goniometer (Erma Optical Works Co. Ltd.). The experiment was carried out at room temperature with 0.9 μl drops. The contact angle was calculated as the mean of fifteen measurements, and it was of 133±2°, indicating a high degree of hydrophobicity (FIG. 11A). When an oil drop was deposited on the same material, it was not repelled but the surfaces proved to be superoleophilic (FIG. 11B).

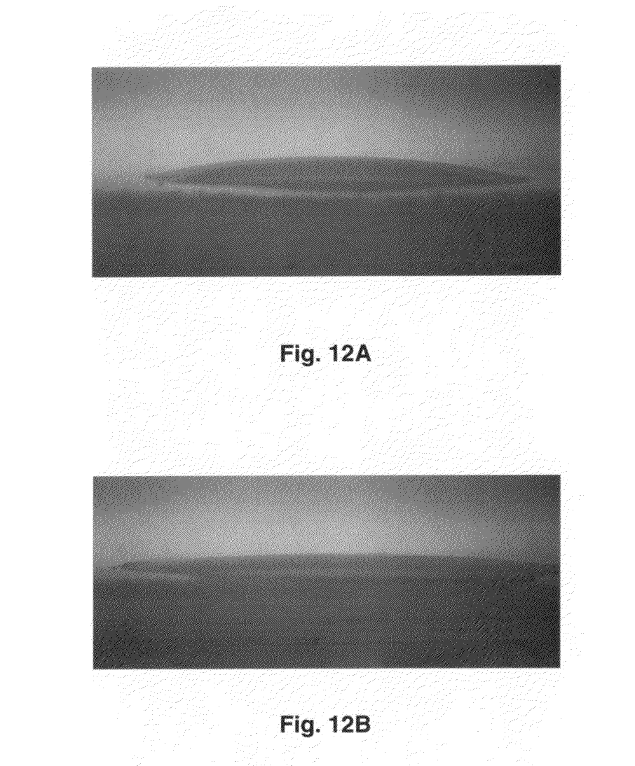

Another material sample, obtained as in Example 1, was exposed to UV radiation at a power of 4000 μW/cm² for 10 minutes. When measuring as explained above the wettability (hydrophobicity) of the UV treated material, it showed a hydrophilic behavior (FIG. 12A), while keeping its superoleophilic properties (FIG. 12B).

### Example 8

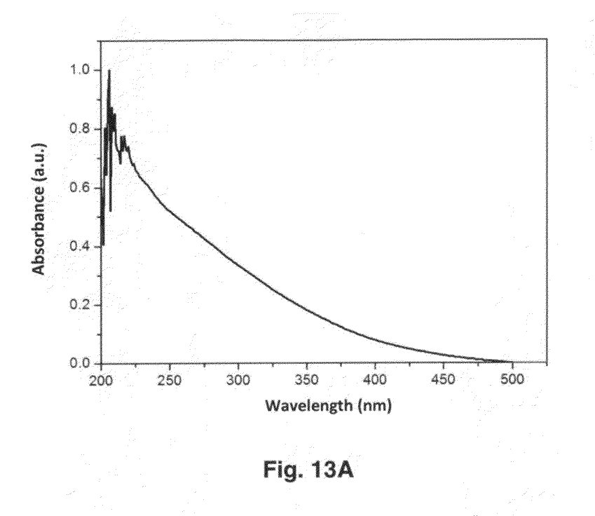

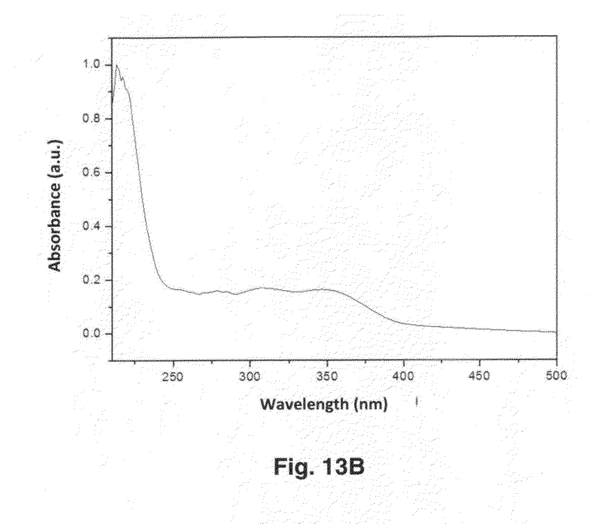

The UV-visible absorption spectrum of the material obtained in Example 1 was determined with a spectrophotometer Shimadzu UV-1800 in transmittance mode. The obtained UV-visible spectrum is shown in FIG. 13A, wherein it can be seen the presence of a wide band, associated to the π-π* transitions, with an absorption maximum at λ=220 nm.

Another sample of material deposited on a quartz substrate in the same conditions as in Example 1 was exposed to UV radiation at a power of 4000 μW/cm² for 10 minutes. In the respective UV-visible spectrum (FIG. 13B), bands associated with the n-π* transitions corresponding to the presence of carbonyl groups (C═O) can be seen between 320 and 360 nm, confirming the hydrophilic character of the material exposed to UV radiation. In similar additional tests, it was observed that 5 minutes of exposure were enough to produce a change in the hydrophilicity of the material, although at a lesser degree (results not shown).

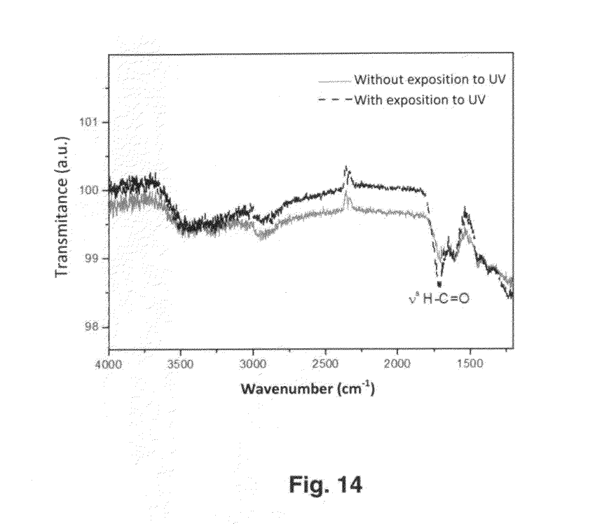

The FTIR spectrum was obtained was obtained using an FT-IR Nicolet 520 spectrometer. When the FTIR spectrum of the material exposed to UV radiation is compared with the FTIR spectrum of the untreated material (FIG. 14) the hydrophilic nature of the treated material is confirmed. An increase of the signal around 3300 cm⁻¹ is observed as a consequence of the O—H stretching of the carboxylic acid group, while the signals centered around 1700 cm⁻¹ corresponds to carbonyl group of the carboxylic acid. The FTIR spectrum of the treated material confirms the oxidative process as a consequence of the UV radiation, wherein the double bonds are transformed into an oxygenated function (for example carboxylic acid group).

### Example 9

The FTIR spectrum of the material of Example 1 reveals carbon-(SP₃)-hydrogen stretching which can be attributed to simple bounds (below 3000 cm⁻¹) and carbon (SP₂)-hydrogen stretching which can be attributed to double bounds (above 3000 cm⁻¹). Additionally, the spectrum presents peaks corresponding to carbon-carbon stretching of simple and double bounds, which can be seen in the area of the digital prints (between 1400 and 1600 cm⁻¹). There are also hydroxyl stretching (O—H), which correspond to the oxygen observed in the microanalysis determination. Such hydroxyls are involved in terminal bounds and/or in —O— bridges.

The results indicate that the material presents a hydrocarbon structure with isolated double bounds, unprotected aliphatic hydrogen atoms, and absence of aromatic protons. In said hydrocarbon structure, carbon-hydrogen bounds involve carbon SP³ bounds and carbon y enlaces de SP² bounds, the bounds between carbon atoms are both by simple and double bounds, and the oxygen atoms are forming terminal hydroxyls, and methylene protons are of the unprotected, protected, and moderately unprotected types.

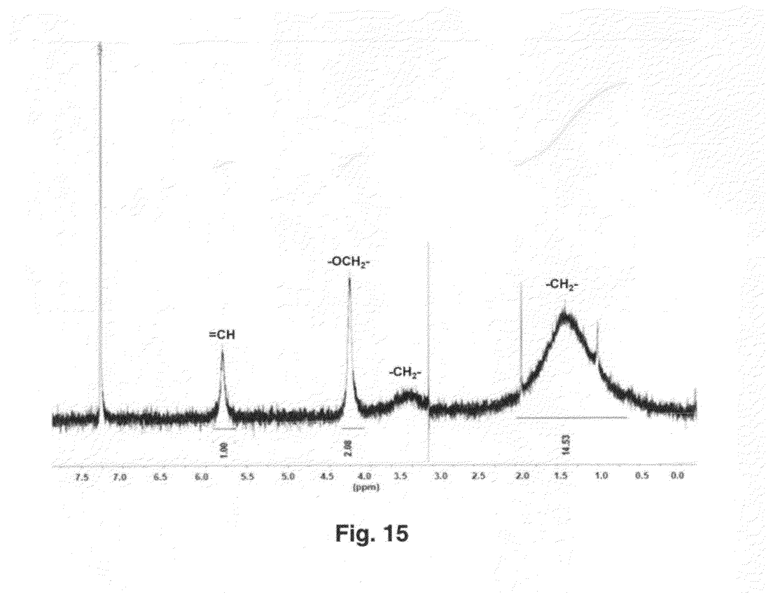

A spectroscopic analysis was performed on the same material of Example 1 using a Burker AC200 spectrometer operated at 200 MHz spectrophotometer and using CDCl₃ as solvent. The obtained ¹H-NMR spectrum is shown in FIG. 15. Different types of protons can be observed consistent with the FTIR data. Signals from unprotected, protected, and moderately unprotected methylene protons are observed, as well as signals from olefinic protons around 5.7 ppm. In FIG. 15 each of the different proton signals of the structure is identified.

### Example 10

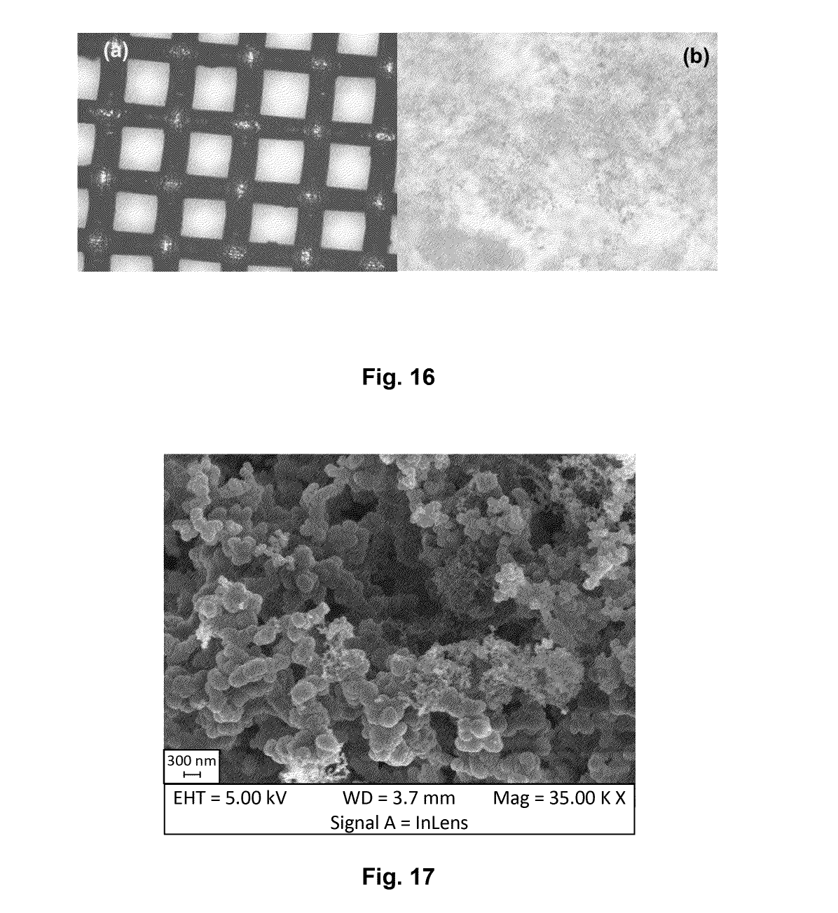

Using the same equipment and conditions as in Example 1, the plasma polymer was deposited on a metallic mesh (FIG. 16a) placed on the grounded electrode. After some minutes of depositing, the polymer completely coated the structure of the mesh but did not close the openings of the same. When depositing was kept for enough additional time, the polymer completely closed the openings of the metallic mesh, what resulted in a sheet of polymer in which the metallic mesh was included, being completely coated (FIG. 16b). The deposited material was yellow, and the microscopic analysis showed similar features to the material obtained in Example 1 (FIG. 17).

### Example 11

Adhesiveness of a polymeric coating to a substrate (quartz, glass or silicone) was qualitatively assessed by the Scotch tape test. An adhesive tape was firmly pressed against an area of the polymeric coating and was pulled off with a single, fast movement. Adhesiveness was evaluated through SEM images of the coating after tape removal. This allowed observing that the material was removed in layers, and when the tape was pulled off only the top layer was removed. For the adhesiveness studies the material was deposited under the conditions described in Example 1 using a reactor of cylindrical configuration as described in Example 4.

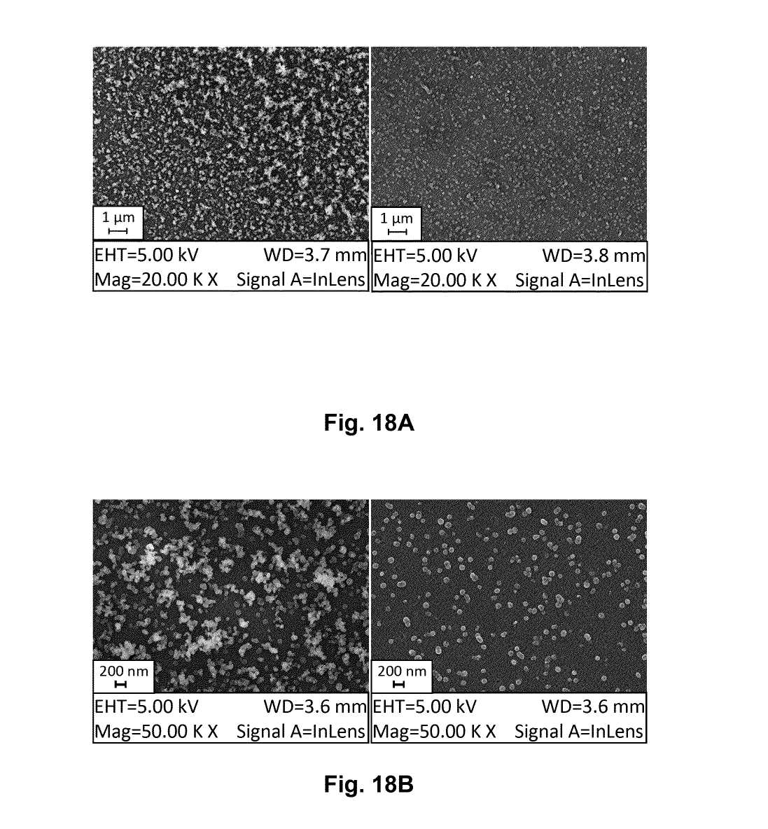

The results demonstrated that adhesiveness is independent from the reactor configuration and working conditions for the claimed range. As an example, the result of the test of a sample in which depositing was carried out for 1 minute (FIG. 18 (F1-F2)) compared with a sample in which depositing was carried out for 30 seconds (FIG. 18 (F3-F4)). In the case of FIG. 18F2 it can be seen that in addition to the material of the layer deposited on the substrate there is remaining material from the second layer.

It was observed that even if a small amount of nanoparticles are removed from the substrate (less than 10%), there is good adhesiveness of the nanoparticles to the substrate.

FIGS. 18 F2 y F4 show that the outermost layers of material are removed by the Scotch tape test.

### Example 12

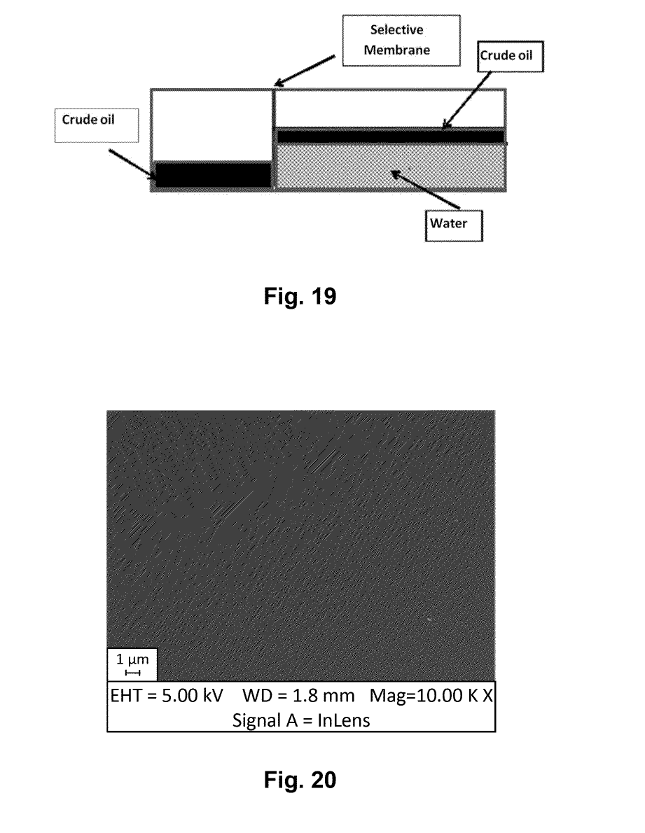

A nanoporous material membrane was produced as in Example 4, using fabric of synthetic polymeric fibers or of natural fibers as substrate, which was coated in only one of its sides. The membrane was placed as a divider in a cell (see FIG. 19), thus splitting said cell in two partitions. The partition on the side of the membrane coated by polymer was filled with a mixture of water and crude oil, so that the coated side was facing the mixture. The nanoporous material coating started to absorb the hydrocarbon until it was saturated. Once the absorption ability of the membrane was saturated, the absorbed crude started to permeate to the opposite side due to the concentration gradient (see left side partition in the outline of FIG. 19). As the membrane is highly hydrophobic, only the hydrocarbon selectively permeates through it.

### Example 13

### Comparison with Prior Art

Using the same equipment of Example 1 and depositing conditions described in Arias-Durán et al. (pressure kept constant at 0.12 mbar, RF power kept at 50 W, with a gas inflow of 20 SCCM), depositing of plasma polymer was carried out on silicon, quartz and glass substrates placed on the grounded electrode. Depositing went on for 10 min., after which a material was obtained which had poor adhesiveness to the substrate, to the point of spontaneously peeling off from it. The microscopic analysis showed that the material was deposited as a continuous film, as it can be seen in FIG. 20.

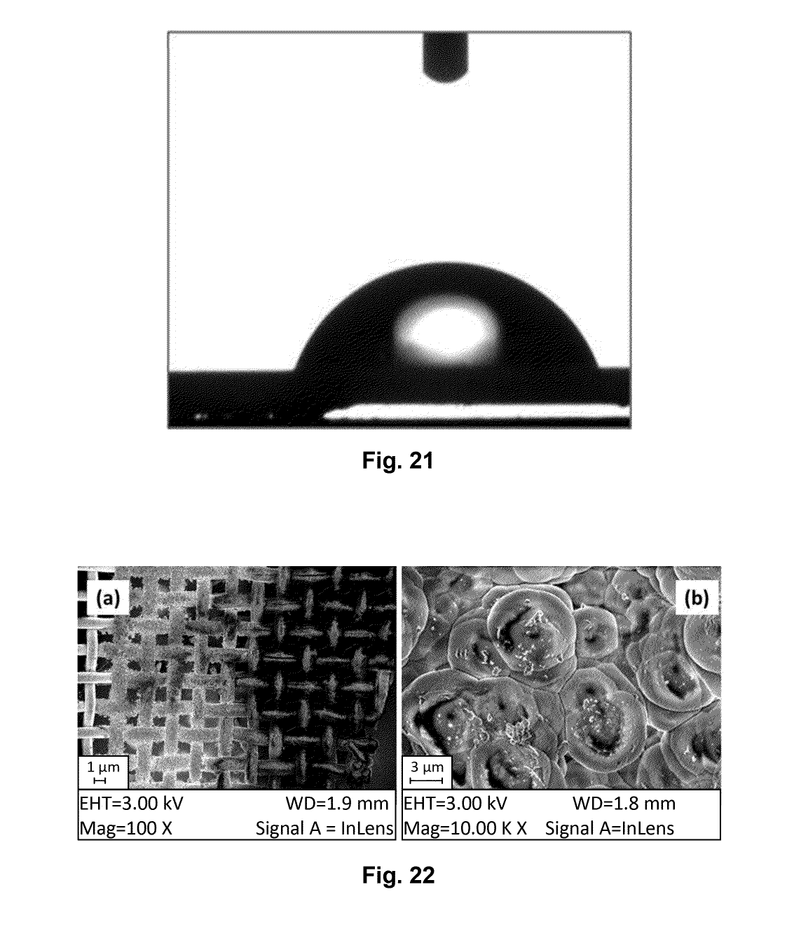

When hydrophobicity of this material was analyzed as explained in Example 7, the water contact angle was 66±1° (FIG. 21), meaning that it is slightly hydrophilic according to the classification of Forch et al. (2009).

### Example 14

### Comparison with Prior Art

Using the same equipment of Example 1 and depositing conditions described in patent application US 2014/0116936 A1 (pressure kept constant at 0.4 mbar, RF power kept at 211 W and bias Voltage of −650 V), the plasma polymer was deposited on a metallic mesh connected to the grounded electrode. After the depositing period, a scarce amount of brown material was obtained, and the structure of the mesh was not completely coated by the polymer (FIG. 22a). Microscopic analysis showed that the deposited material was formed by lenticular particles of between about 2 and 6 μm (2000-6000 nm) in diameter and did not present the lattice appearance of the materials obtained at higher depositing pressures (FIG. 22b).

### Example 15

### Comparison with Prior Art

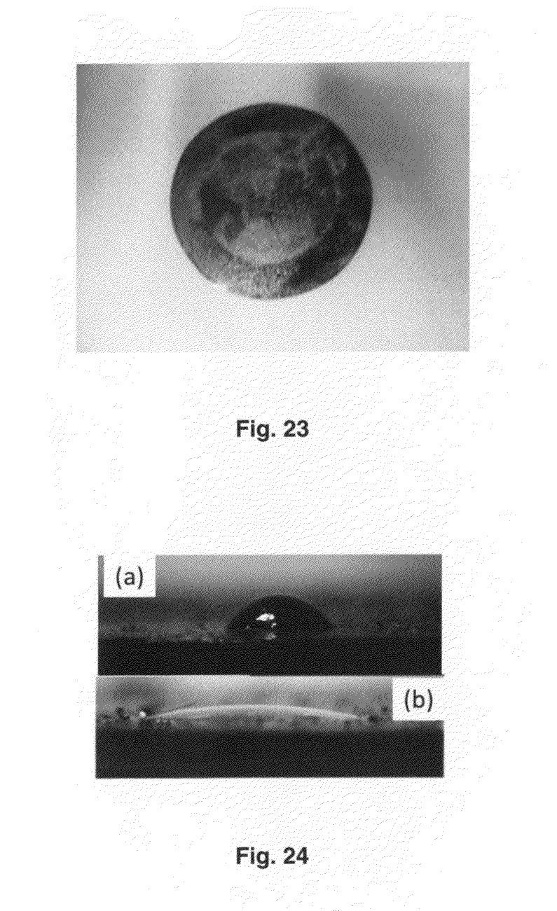

Using the same equipment and conditions of Example 14, plasma polymer was deposited on a glass substrate. Depositing was kept for 10 minutes, after which the structure of the mesh was not completely coated by the polymer (FIG. 23). The obtained material, of brown color, had poor adhesiveness to the substrate, and was easily peeled off from the substrate. In the hydrophobicity assays carried out as explained in Example 7, water contact angle measured for the material of this example was 52°±2°, while the oil contact angle was 16°±2° (FIGS. 24a and 24b, respectively). The assays were performed in the parts of the substrate in which the glass was completely coated by the polymer.

1. A nanoporous material made of aggregated polymeric nanoparticles, wherein the polymer has a spatial conformation of open network comprising the repetitive hydrocarbon structure of formula I: 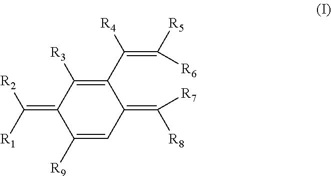
wherein R1-R9 are molecular groups which bind with other structures of formula I, each independently selected from H, (C₁₋₅) alkylene- or (C₆₋₁₀) cycloalkylen-(C₁₋₅) alkylene-;
wherein the alkylene groups can be saturated or have one or more carbon-carbon double bonds, wherein the groups cycloalkylene have one or more carbon-carbon double bonds, and wherein one or more carbon atoms of the alkylene and cycloalkylene chains can be substituted by a —O— bridge or by —OH,
and wherein at least 40% of the nanoparticles have a diameter above 50 nm.

2. The nanoporous material of claim 1, wherein the alkylene binding molecular group is —CH₂—CH═CH— or —CH═CH—.

3. The nanoporous material of claim 1, wherein the cycloalkylene binding molecular group is —C₆H₈— and has at least one insaturation.

4. The nanoporous material of claim 1, wherein at least 60% of the nanoparticles has a diameter above 50 nm.

5. The nanoporous material of claim 1, wherein said nanoparticles have a diameter between 8 and 200 nm.

6. The nanoporous material of claim 1, wherein the specific surface area of said material, measured according to the BET (Brunauer-Emmett-Teller) method, is between 141 y 173 m²/g.

7. The nanoporous material of claim 6, wherein the specific surface area is 157 m²/g

8. The nanoporous material of claim 1, wherein the pores of radius equal or less than 2 nm contribute with at least 60% of the porosity measured according to the BJH (Barrett, Joyner & Halenda) method.

9. The nanoporous material of claim 8, wherein the contribution to porosity of each pore size has the following distribution:

| Mean radius of the pore (nm) | Contribution to total pore area (%) |
|---|---|
| 114.54 | 0.61 ± 0.06 |
| 61.92 | 1.13 ± 0.11 |
| 42.07 | 0.96 ± 0.10 |
| 23.67 | 2.74 ± 0.27 |
| 15.40 | 2.25 ± 0.23 |
| 11.32 | 2.09 ± 0.21 |
| 8.91 | 1.96 ± 0.20 |
| 7.35 | 1.93 ± 0.19 |
| 6.13 | 2.29 ± 0.23 |
| 5.35 | 1.59 ± 0.16 |
| 4.45 | 3.38 ± 0.34 |
| 3.62 | 3.46 ± 0.35 |
| 3.04 | 4.47 ± 0.45 |
| 2.60 | 3.88 ± 0.39 |
| 2.26 | 4.31 ± 0.43 |
| 1.99 | 4.62 ± 0.46 |
| 1.76 | 4.88 ± 0.49 |
| 1.56 | 5.28 ± 0.53 |
| 1.40 | 5.92 ± 0.59 |
| 1.25 | 7.52 ± 0.75 |
| 1.11 | 9.51 ± 0.95 |
| 0.98 | 10.52 ± 1.05 |
| 0.91 | 7.10 ± 0.71 |
| 0.86 | 7.59 ± 0.76 |

10. The nanoporous material of claim 1, wherein the polymer comprises at least 68% of carbon and at least 5% of hydrogen.

11. The nanoporous material of claim 10, wherein the polymer comprises oxygen in a percentage below 20%.

12. A process for producing a nanoporous material made of aggregated polymeric nanoparticles, which comprises carrying out a plasma polymerization comprising the steps of:
a. feeding a plasma reactor with a carbon source selected from the group consisting of acetylene, methane, ethane, benzene, and combinations thereof, and
b. performing and maintaining the discharge of radiofrequency using a power in the range of 20-550 W at a pressure equal to or higher than 1 mbar.

13. The process of claim 12, wherein the carbon source is acetylene.

14. The process of claim 12, wherein said process is performed with a continuous voltage bias between −3 V and −450 V.

15. A nanoporous material produced by the process of claim 12.

16. The nanoporous material of claim 15, wherein said nanoporous material is in the form of a sheet.

17. The nanoporous material of claim 15, wherein said nanoporous material is in the form of a powder.

18. A process for coating at least a surface of a substrate with a nanoporous material made of aggregated polymeric nanoparticles, wherein said process comprises the steps of:
a. providing the substrate whose coating is desired inside a plasma reactor,
b. feeding the plasma reactor with a carbon source selected from the group consisting of acetylene, methane, ethane, benzene, and combinations thereof, and
c. performing and maintaining the discharge of radiofrequency using a power in the range of 20-550 W at a pressure equal to or higher than 1 mbar.

19. The process of claim 18, which is carried out with a continuous voltage bias between −3 V y −450 V.

20. The process of claim 18, wherein the substrate is a glass, metal, ceramic, or polymeric sheet, and the nanoporous material forms a film on at least one of its surfaces.

21. A selective absorption membrane for hydrocarbons or mineral, animal or vegetable oils comprising a nanoporous material formed by aggregated polymeric nanoparticles, wherein the polymer has a spatial conformation of open network comprising the repetitive hydrocarbon structure of formula I: 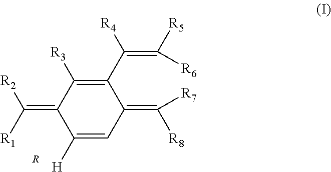
wherein R₁-R₉ are molecular groups which bind with other structures of formula I, each independently selected from H, (C₁₋₅) alkylene- or (C₆₋₁₀) cycloalkylen-(C₁₋₅) alkylene-;
wherein the alkylene groups can be saturated or have one or more carbon-carbon double bonds, wherein the groups cycloalkylene have one or more carbon-carbon double bonds, and wherein one or more carbon atoms of the alkylene and cycloalkylene chains can be substituted by a —O— bridge or by —OH,
wherein at least 40% of the nanoparticles has a diameter above 50 nm, and wherein said nanoporous material coats at least one side of a substrate selected from a metallic mesh, a synthetic fibers mesh, or a natural fibers mesh, such as a fabric of synthetic polymeric fibers or a fabric of natural fibers.

22. The membrane of claim 21, wherein alkylene binding molecular group is —CH₂—CH═CH— or —CH═CH—.

23. The membrane of claim 21, wherein cycloalkylene binding molecular group is —C₆H₈— and has at least one insaturation.

24. The membrane of claim 21, wherein the nanoporous material coats only one side of the substrate.

25. The membrane of claim 21, wherein at least 60% of the nanoparticles has a diameter above 50 nm.

26. The membrane of claim 21, wherein the specific surface area of the nanoporous material, measured according to the BET (Brunauer-Emmett-Teller) method, is between 141 and 173 m²/g.

27. The membrane of claim 26, wherein the specific surface area is 157 m²/g.

28. The membrane of claim 21, wherein the pores of radius equal or less than 2 nm contribute with at least 60% of the porosity measured according to the BJH (Barrett, Joyner & Halenda) method.

29. The membrane of claim 28, wherein the contribution to porosity of each pore size has the following distribution:

| Mean radius of the pore (nm) | Contribution to total pore area (%) |
|---|---|
| 114.54 | 0.61 ± 0.06 |
| 61.92 | 1.13 ± 0.11 |
| 42.07 | 0.96 ± 0.10 |
| 23.67 | 2.74 ± 0.27 |
| 15.40 | 2.25 ± 0.23 |
| 11.32 | 2.09 ± 0.21 |
| 8.91 | 1.96 ± 0.20 |
| 7.35 | 1.93 ± 0.19 |
| 6.13 | 2.29 ± 0.23 |
| 5.35 | 1.59 ± 0.16 |
| 4.45 | 3.38 ± 0.34 |
| 3.62 | 3.46 ± 0.35 |
| 3.04 | 4.47 ± 0.45 |
| 2.60 | 3.88 ± 0.39 |
| 2.26 | 4.31 ± 0.43 |
| 1.99 | 4.62 ± 0.46 |
| 1.76 | 4.88 ± 0.49 |
| 1.56 | 5.28 ± 0.53 |
| 1.40 | 5.92 ± 0.59 |
| 1.25 | 7.52 ± 0.75 |
| 1.11 | 9.51 ± 0.95 |
| 0.98 | 10.52 ± 1.05 |
| 0.91 | 7.10 ± 0.71 |
| 0.86 | 7.59 ± 0.76 |

30. The membrane of claim 21, wherein the polymer comprises at least 68% of carbon and at least 5% of hydrogen.

31. The membrane of claim 30, wherein the polymer also comprises oxygen in a percentage below 20%.

32. The membrane of claim 21, wherein the substrate is a metallic mesh.

33. The membrane of claim 21, wherein the substrate is a synthetic or natural fibers mesh.

34. A process for manufacturing a membrane according to claim 21, said process comprising the steps of:
a. providing a substrate inside a plasma reactor, being said substrate selected from a metallic mesh, a polymeric fibers mesh, or a natural fibers mesh,
b. feeding the plasma reactor with a carbon source selected from the group consisting of acetylene, methane, ethane, benzene, and combinations thereof, and
c. performing and maintaining a discharge of radiofrequency with a power in the range of 20-550 W at a pressure equal to or higher than 1 mbar.

35. The process of claim 34, said process being performed with a continuous bias voltage between −3 V and −450 V, more preferably, −5 V or −10 V.

36. The process of claim 34, wherein the carbon source is acetylene.

37. The process of claim 34, wherein the plasma reactor is a flat geometry or a cylindrical geometry plasma reactor.

38. The process of claim 34, wherein the radiofrequency discharge is kept at a power of 25 W and the working pressure is 2 mbar, and wherein the reactor has a flat geometry.

39. The process of claim 34, wherein the radiofrequency discharge is kept at a power of 45 W and the working pressure is 5 mbar, and wherein the reactor has a cylindrical geometry.

40. The process of claim 34, wherein the radiofrequency discharge is kept at a power of 210 W and the working pressure is 7 mbar, and wherein the reactor has a cylindrical geometry.

41. A process for removing hydrophobic compounds from its mixtures in water, said process comprising contacting said mixture with the side coated by nanoporous material of the selective absorption membrane of claim 24.

42. The process of claim 41, wherein the hydrophobic compound(s) are paraffins, oleffins, petroleum or its derivatives, or aromatic compounds.

43. The process of claim 41, wherein the hydrophobic compound(s) are animal or vegetable oils or fats.

44. The process of claim 41, wherein the membrane separates two compartments, a first compartment, on the side of the membrane that is coated by nanoporous material and wherein the mixture of water and hydrophobic compounds is located; and a second compartment on the side of the membrane which is not coated by nanoporous material, wherein the second compartment receives the hydrophobic compounds once these have been separated from the water.
